(19) United States
(12) Patent Application Publication
(10) Pub. No.: US 2022/0093579 A1
(43) Pub. Date: Mar. 24, 2022

(54) MICRO LED DEVICE AND METHOD FOR MANUFACTURING SAME

(71) Applicant: SAKAI DISPLAY PRODUCTS CORPORATION, Sakai-shi, Osaka (JP)

(72) Inventor: KATSUHIKO KISHIMOTO, Sakai-shi, Osaka (JP)

(21) Appl. No.: 17/425,523

(22) PCT Filed: Jan. 28, 2019
(86) PCT No.: PCT/JP2019/002816

§ 371 Date: Jul. 23, 2021

(51) Int. Cl. H01L 25/16; H01L 33/62; H01L 33/00

(52) U.S. Cl. CPC H01L 25/167; H01L 2933/0066; H01L 33/0093; H01L 33/62

(57) ABSTRACT

A micro-LED device of the present disclosure includes a frontplane (200) that includes a plurality of micro-LEDs (220), each of which includes a first semiconductor layer (21) of a first conductivity type and a second semiconductor layer (22) of a second conductivity type, and a device isolation region (240) located between the micro-LEDs. The device isolation region includes at least one metal plug (24) electrically coupled with the second semiconductor layer. This device includes a middle layer (300) which includes first contact electrodes (31) electrically coupled with the first semiconductor layer and a second contact electrode (32) coupled with the metal plug, and a backplane (400) provided on the middle layer. This device further includes a supporting substrate (500) secured to at least one of the backplane and the frontplane.

### TECHNICAL FIELD

The present disclosure relates to a micro-LED device and a method for producing the same.

### BACKGROUND ART

To realize a practical display device which includes a large number of micro-LEDs arrayed at a narrow pitch, it is necessary to develop mass production techniques for mounting microscopic micro-LEDs at predetermined positions on a circuit board such as TFT substrate. According to the technique of mounting each of the micro-LEDs to a circuit by a pick-and-place method, mounting a large number of micro-LEDs to a circuit at a pitch of, for example, several tens of micrometers needs a very long work time.

Patent Document No. 1 discloses a display device which includes a large number of micro-LEDs transferred onto a TFT substrate and a method for producing the display device.

Patent Document No. 2 discloses a display device that includes a GaN wafer where a plurality of LEDs are formed and a backplane control section (TFT substrate) to which the GaN wafer is joined and a method for producing the display device.

### CITATION LIST

### Patent Literature

Patent Document No. 1: Japanese PCT National Phase Laid-Open Patent Publication No. 2016-522585

Patent Document No. 2: Japanese PCT National Phase Laid-Open Patent Publication No. 2017-538290

### SUMMARY OF INVENTION

### Technical Problem

The method of transferring a large number of micro-LEDs onto a TFT substrate has greater difficulty in positioning the micro-LEDs relative to the TFT substrate as the size of the micro-LEDs decreases and the number of the micro-LEDs increases. The method of joining a GaN wafer to a backplane control section needs a complicated step which includes transferring a GaN wafer to another wafer for temporal storage and then mounting it to the backplane control section.

The present disclosure provides a novel configuration and production method of a micro-LED device, which can solve the above-described problems.

### Solution to Problem

A micro-LED device of the present disclosure includes, in an exemplary embodiment: a supporting substrate; a frontplane including a plurality of micro-LEDs, each of which includes a first semiconductor layer of a first conductivity type and a second semiconductor layer of a second conductivity type, and a device isolation region located between the plurality of micro-LEDs, the device isolation region including at least one metal plug electrically coupled with the second semiconductor layer; a middle layer supported by the frontplane, the middle layer including a plurality of first contact electrodes respectively electrically coupled with the first semiconductor layer of the plurality of micro-LEDs and at least one second contact electrode coupled with the metal plug; and a backplane supported by the middle layer, the backplane including an electric circuit electrically coupled with the plurality of micro-LEDs via the plurality of first contact electrodes and the at least one second contact electrode, the electric circuit including a plurality of thin film transistors. The frontplane, the middle layer and the backplane are divided into a plurality of light-emitting device units which are two-dimensionally arrayed, the plurality of light-emitting device units being supported by the supporting substrate, and each of the plurality of thin film transistors includes a semiconductor layer deposited on the frontplane and/or the middle layer.

In one embodiment, the supporting substrate includes an expandable film drawn out in an in-plane direction.

In one embodiment, in each of the plurality of light-emitting device units, the device isolation region of the frontplane includes an insulator covering a side surface of the plurality of micro-LEDs, the insulator having at least one through hole for the metal plug.

In one embodiment, in each of the plurality of light-emitting device units, the frontplane has a flat surface, and the flat surface is in contact with the middle layer.

In one embodiment, in each of the plurality of light-emitting device units, the middle layer includes an interlayer insulating layer having a flat surface, and the interlayer insulating layer has a plurality of contact holes for coupling the plurality of first contact electrodes and the at least one second contact electrode with the electric circuit.

In one embodiment, each of the plurality of light-emitting device units includes a plurality of micro-LEDs, each of the plurality of light-emitting device units having an electrically-conductive layer which electrically couples the second semiconductor layers of the micro-LEDs.

A micro-LED device production method of the present disclosure includes, in an exemplary embodiment: providing a multilayer stack which includes a frontplane supported by a crystal growth substrate, the frontplane including a plurality of micro-LEDs, each of which includes a first semiconductor layer of a first conductivity type and a second semiconductor layer of a second conductivity type, and a device isolation region located between the plurality of micro-LEDs, the device isolation region including at least one metal plug electrically coupled with the second semiconductor layer, and a middle layer supported by the frontplane, the middle layer including a plurality of first contact electrodes respectively electrically coupled with the first semiconductor layer of the plurality of micro-LEDs and at least one second contact electrode coupled with the metal plug; forming a backplane on the multilayer stack, the backplane including an electric circuit electrically coupled with the plurality of micro-LEDs via the plurality of first contact electrodes and the at least one second contact electrode, the electric circuit including a plurality of thin film transistors; dividing the multilayer stack and the backplane into a plurality of light-emitting device units; covering the backplane with an expandable film and securing the multilayer stack and the backplane to the expandable film; a delamination step which includes delaminating the multilayer stack, the backplane and the expandable film from the crystal growth substrate; and expanding the expandable film, thereby enlarging a gap between the plurality of light-emitting device units. Forming the backplane includes depositing a semiconductor layer on the multilayer stack, and patterning the semiconductor layer deposited on the multilayer stack.

In one embodiment, the expandable film is used as at least part of a flexible substrate supporting the plurality of light-emitting device units secured to the expandable film.

In one embodiment, the method includes transferring onto a supporting substrate the plurality of light-emitting device units secured to the expandable film.

In one embodiment, dividing the multilayer stack and the backplane into the plurality of light-emitting device units includes forming a cut groove from the backplane side so as to reach the crystal growth substrate.

In one embodiment, dividing the multilayer stack and the backplane into the plurality of light-emitting device units includes securing the crystal growth substrate to a dicing tape, and forming a cut groove from the backplane side so as to reach a middle section or a lower surface of the crystal growth substrate.

In one embodiment, dividing the multilayer stack and the backplane into the plurality of light-emitting device units includes forming a cut groove from the backplane side so as not to reach the crystal growth substrate.

In one embodiment, dividing the multilayer stack and the backplane into the plurality of light-emitting device units includes, after the delamination step, performing a breaking step which includes splitting the multilayer stack at the cut groove.

In one embodiment, the delamination step includes irradiating an interface between the crystal growth substrate and the frontplane with light transmitted through the crystal growth substrate.

A micro-LED device production method of the present disclosure includes, in an exemplary embodiment: providing a multilayer stack which includes a frontplane supported by a crystal growth substrate, the frontplane including a plurality of micro-LEDs, each of which includes a first semiconductor layer of a first conductivity type and a second semiconductor layer of a second conductivity type, and a device isolation region located between the plurality of micro-LEDs, the device isolation region including at least one metal plug electrically coupled with the second semiconductor layer, and a middle layer supported by the frontplane, the middle layer including a plurality of first contact electrodes respectively electrically coupled with the first semiconductor layer of the plurality of micro-LEDs and at least one second contact electrode coupled with the metal plug; forming a backplane on the multilayer stack, the backplane including an electric circuit electrically coupled with the plurality of micro-LEDs via the plurality of first contact electrodes and the at least one second contact electrode, the electric circuit including a plurality of thin film transistors; covering the backplane with an expandable film and securing the multilayer stack and the backplane to the expandable film; a delamination step which includes delaminating the multilayer stack, the backplane and the expandable film from the crystal growth substrate; performing dicing on the device isolation region, thereby dividing the multilayer stack and the backplane into a plurality of light-emitting device units each supported by the expandable film, and expanding the expandable film, thereby enlarging a gap between the plurality of light-emitting device units. Forming the backplane includes depositing a semiconductor layer on the multilayer stack, and patterning the semiconductor layer deposited on the multilayer stack.

In one embodiment, the expandable film is used as at least part of a flexible substrate supporting the plurality of light-emitting device units secured to the expandable film.

In one embodiment, the method includes transferring onto a supporting substrate the plurality of light-emitting device units secured to the expandable film.

In one embodiment, dividing the multilayer stack and the backplane into the plurality of light-emitting device units includes forming a cut groove in the multilayer stack and the backplane so as not to reach the expandable film.

In one embodiment, dividing the multilayer stack and the backplane into the plurality of light-emitting device units includes, after the dicing, performing a breaking step which includes splitting the multilayer stack at the cut groove.

In one embodiment, the delamination step includes irradiating an interface between the crystal growth substrate and the frontplane with light transmitted through the crystal growth substrate.

### Advantageous Effects of Invention

According to an embodiment of the present invention, a micro-LED device and a production method thereof are provided which can solve the above-described problems.

### BRIEF DESCRIPTION OF DRAWINGS

FIG. 1A is a cross-sectional view showing part of a μLED device 1000 of the present disclosure.

FIG. 1B is a plan view showing an arrangement example of μLEDs 220 in the μLED device 1000.

FIG. 1C is a cross-sectional view showing part of the μLED device 1000 of the present disclosure in the middle of the production process.

FIG. 2 is a perspective view showing an arrangement example of first contact electrodes 31 and second contact electrodes 32 in the μLED device 1000.

FIG. 3 is a circuit diagram showing an example of part of an electric circuit in the μLED device 1000.

FIG. 4A is a perspective view schematically showing a production step of the μLED device 1000.

FIG. 4B is a perspective view schematically showing a production step of the μLED device 1000.

FIG. 4C is a perspective view schematically showing a production step of the μLED device 1000.

FIG. 4D is a perspective view schematically showing a production step of the μLED device 1000.

FIG. 4E is a perspective view schematically showing a production step of the μLED device 1000.

FIG. 4F is a perspective view schematically showing a production step of the μLED device 1000.

FIG. 4G is a perspective view schematically showing a production step of the μLED device 1000.

FIG. 4H is a perspective view schematically showing a production step of the μLED device 1000.

FIG. 5 is a perspective view showing part of the μLED device 1000 which includes μLEDs 220 in the shape of a cylindrical pillar.

FIG. 6 is a cross-sectional view of a μLED device 1000A in an embodiment of the present disclosure.

FIG. 7A is a cross-sectional view schematically showing a production step of the μLED device 1000A.

FIG. 7B is a cross-sectional view schematically showing a production step of the μLED device 1000A.

FIG. 7C is a cross-sectional view schematically showing a production step of the μLED device 1000A.

FIG. 7D is a cross-sectional view schematically showing a production step of the μLED device 1000A.

FIG. 7E is a cross-sectional view schematically showing a production step of the μLED device 1000A.

FIG. 7F is a cross-sectional view schematically showing a production step of the μLED device 1000A.

FIG. 7G is a cross-sectional view schematically showing a production step of the μLED device 1000A.

FIG. 7H is a cross-sectional view schematically showing a production step of the μLED device 1000A.

FIG. 7I is a cross-sectional view schematically showing a production step of the μLED device 1000A.

FIG. 7J is a cross-sectional view schematically showing a production step of the μLED device 1000A.

FIG. 7K is a cross-sectional view schematically showing a production step of the μLED device 1000A.

FIG. 7L is a cross-sectional view schematically showing a production step of the μLED device 1000A.

FIG. 8A is a plan view schematically showing a production step of the μLED device 1000A.

FIG. 8B is a plan view schematically showing a production step of the μLED device 1000A.

FIG. 9A is a cross-sectional view schematically showing a production step of the μLED device 1000A.

FIG. 9B is a cross-sectional view schematically showing a production step of the μLED device 1000A.

FIG. 9C is a cross-sectional view schematically showing a production step of the μLED device 1000A.

FIG. 9D is a cross-sectional view schematically showing a production step of the μLED device 1000A.

FIG. 9E is a cross-sectional view schematically showing a production step of the μLED device 1000A.

FIG. 10 is a cross-sectional view showing still another configuration example of the μLED device 1000A in an embodiment of the present disclosure.

FIG. 11A is a cross-sectional view schematically showing a production step of the μLED device 1000A.

FIG. 11B is a cross-sectional view schematically showing a production step of the μLED device 1000A.

FIG. 11C is a cross-sectional view schematically showing a production step of the μLED device 1000A.

FIG. 11D is a cross-sectional view schematically showing a production step of the μLED device 1000A.

FIG. 11E is a cross-sectional view schematically showing a production step of the μLED device 1000A.

FIG. 11F is a cross-sectional view schematically showing a production step of the μLED device 1000A.

FIG. 12A is a cross-sectional view schematically showing a production step of the μLED device 1000A in another embodiment of the present disclosure.

FIG. 12B is a cross-sectional view schematically showing a production step of the μLED device 1000A.

FIG. 12C is a cross-sectional view schematically showing a production step of the μLED device 1000A.

FIG. 13A is a cross-sectional view schematically showing a production step of the μLED device 1000A in still another embodiment of the present disclosure.

FIG. 13B is a cross-sectional view schematically showing a production step of the μLED device 1000A.

FIG. 14 is a cross-sectional view schematically showing a configuration of a μLED device 1000B in still another embodiment of the present disclosure.

FIG. 15 is a cross-sectional view schematically showing a configuration of a μLED device 1000C in still another embodiment of the present disclosure.

FIG. 16 is a perspective view schematically showing a configuration of the μLED device 1000C of FIG. 15.

FIG. 17 is a cross-sectional view schematically showing a configuration of a μLED device 1000D in still another embodiment of the present disclosure.

FIG. 18 is a cross-sectional view schematically showing a configuration of a μLED device 1000E in still another embodiment of the present disclosure.

### DESCRIPTION OF EMBODIMENTS

### Definitions

In the present disclosure, “micro-LED” means a light emitting diode (LED) whose occupation region can be included within an area of 100 μm×100 μm. “Light” emitted by the micro-LED is not limited to visible light but includes a wide variety of electromagnetic waves including visible, ultraviolet, and infrared. Hereinafter, “micro-LED” is also referred to as “μLED”.

μLEDs have a first semiconductor layer of the first conductivity type and a second semiconductor layer of the second conductivity type. The first conductivity type is one of p-type and n-type. The second conductivity type is the other of p-type and n-type. For example, if the first conductivity type is p-type, the second conductivity type is n-type. If, on the contrary, the first conductivity type is n-type, the second conductivity type is p-type. Each of the first semiconductor layer and the second semiconductor layer can have a single-layer structure or a multilayer structure. Typically, an emission layer which has at least one quantum well (or double heterostructure) is provided between the first semiconductor layer and the second semiconductor layer.

In the present disclosure, “micro-LED device (μLED device)” refers to a device which includes a plurality of μLEDs. The plurality of μLEDs in the μLED device are also referred to as “μLED array”. A typical example of the μLED device is a display device, although the μLED device is not limited to a display device.

<Basic Configuration>

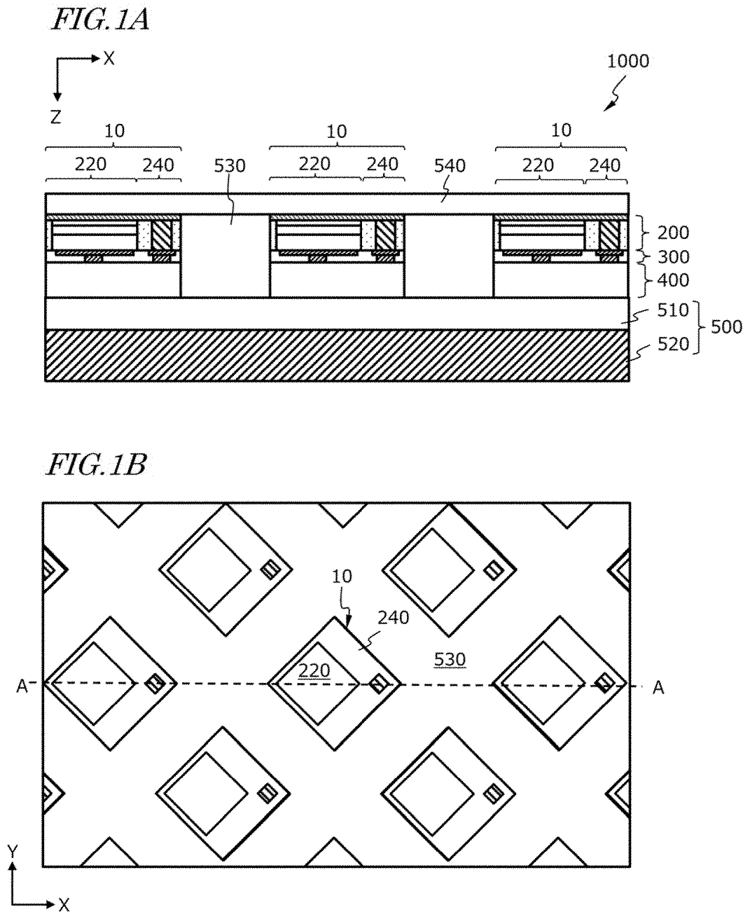

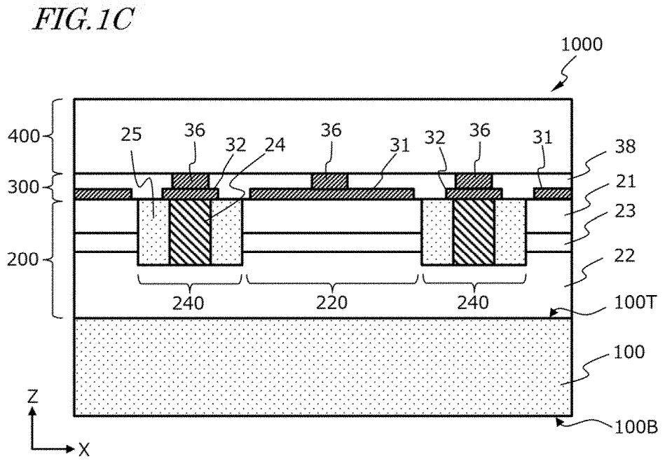

A basic configuration example of a μLED device of the present disclosure is described with reference to FIG. 1A and FIG. 1B. FIG. 1A is a cross-sectional view showing part of a μLED device 1000. FIG. 1B is a plan view showing an arrangement example of a μLED array in the μLED device 1000. The cross section of the μLED device 1000 shown in FIG. 1A is identical with the cross section taken along line A-A of FIG. 1B.

The μLED device 1000 can include a large number of μLEDs, for example, more than 1,000,000 μLEDs. FIG. 1A and FIG. 1B show only a part of the μLED device 1000 which includes several μLEDs. The entirety of the μLED device 1000 has a configuration where the shown part is periodically repeated.

The μLED device 1000 includes a supporting substrate 500, a frontplane 200 supported by the supporting substrate 500, a middle layer 300 supported by the frontplane 200, and a backplane 400 supported by the middle layer.

The frontplane 200, the middle layer 300 and the backplane 400 are supported by the supporting substrate 500 while they are divided into a plurality of light-emitting device units 10 which are two-dimensionally arrayed. Each of the light-emitting device units 10 includes at least one μLED and functions as a light-emitting device. In this example, the supporting substrate 500 includes an expandable film 510 which has been expanded in directions parallel to the XY plane and a support member 520 which secures the expandable film 510. The expandable film 510 typically has the same configuration as a known dicing tape or expansion tape and includes an unshown adhesive layer at the surface. The expandable film 510 is secured to each of the light-emitting device units 10 via this adhesive layer.

In the example shown in FIG. 1A, the expandable film 510 is a constituent of the μLED device 1000 although, in other examples which will be described later, the expandable film 510 is used only in the middle of the production process and is not a constituent of a final-product μLED device 1000. The plurality of light-emitting device units 10 are not covered with a protecting film 540. Instead of the protecting film 540, or together with the protecting film 540, a function layer such as a film including a touch sensor and/or a printed circuit board may be adhered. The space 530 between adjoining light-emitting device units 10 may be filled with an insulative material such as resin or may remain entirely or partially vacant. The side surface of each of light-emitting device units 10 may be covered with an unshown protecting layer. When the protecting film 540, the expandable film 510, the support member 520, etc., are made of a flexible material, the entirety of the μLED device 1000 can function as a flexible device.

In the attached drawings, the proportion of the transverse size to the longitudinal size of respective components such as μLEDs is not necessarily equal to the actual proportion in an embodiment. In the drawings, clarity takes precedence in determining the proportion of the depicted components. The orientation of respective components in the drawings does not limit at all the orientation in actual production of the μLED device and the orientation in actual use of the μLED device. In FIG. 1A and FIG. 1B, a right-handed coordinate system of X-axis, Y-axis and Z-axis, which are mutually orthogonal, is shown for reference.

In one embodiment, the μLED device 1000 of the present disclosure can be produced, as will be described later, by sequentially forming a frontplane 200, a middle layer 300, and a backplane 400 on a crystal growth substrate 100 shown in FIG. 1C and thereafter removing the crystal growth substrate 100. However, the crystal growth substrate 100 may be included as a constituent in a final μLED device 1000, without being delaminated away.

In one embodiment, after the crystal growth substrate 100 is removed by, for example, a laser lift-off method, the step of securing the backplane 400 to an expandable film 510 is carried out. After dicing on the device isolation region 240 is performed from the frontplane 200 side such that the structure is divided into a plurality of light-emitting device units 10, the expandable film 510 is expanded, whereby the gap between the plurality of light-emitting device units 10 is enlarged.

In another embodiment, before the crystal growth substrate 100 is removed, and before the backplane 400 is secured to the expandable film 510, dicing on the device isolation region 240 may be performed from the backplane 400 side such that the structure is divided into a plurality of light-emitting device units 10. Herein, the dicing may be performed such that a cut groove reaches the crystal growth substrate 100 or part of the frontplane 200 remains in a continuous form. After the backplane 400 is adhered to the expandable film 510, the crystal growth substrate 100 is delaminated from the frontplane 200 by, for example, a laser lift-off method. When part of the frontplane 200 is in a continuous form, it can be thoroughly divided for respective ones of the light-emitting device units 10 by applying mechanical force. Thereafter, the expandable film 510 is expanded, whereby the gap between the plurality of light-emitting device units 10 is enlarged.

In still another embodiment, the structure may be divided into a plurality of light-emitting device units 10 by adhering the expandable film 510 to the lower surface of the crystal growth substrate and thereafter performing dicing on the device isolation region 240 from the backplane 400 side. In this case, the dicing may be performed such that a cut groove reaches the lower surface 100B of the crystal growth substrate 100 or such that part of the crystal growth substrate 100 remains in a continuous form. When part of the crystal growth substrate 100 is in a continuous form, the crystal growth substrate 100 can also be thoroughly divided for respective ones of the light-emitting device units 10 by applying mechanical force. Thereafter, the expandable film 510 is expanded, whereby the gap between the plurality of light-emitting device units 10 is enlarged. In this example, the divisional pieces of the crystal growth substrate 100 remain attached to the frontplane 200 of the light-emitting device units 10 and function as constituents of a final μLED device 1000. When the crystal growth substrate 100 is divided, the thickness of the crystal growth substrate 100 can be set in the range of, for example, 30-150 μm.

In still another embodiment, after the crystal growth substrate 100 is delaminated from the frontplane 200 and the expandable film 510 is adhered to the delaminated surface of the frontplane 200, the dicing may be performed from the backplane 400 side. After the structure is divided into a plurality of light-emitting device units 10 by the dicing, the expandable film 510 is expanded, whereby the gap between the plurality of light-emitting device units 10 is enlarged.

Since the expandable film 510 has flexibility, the expandable film 510 can be used as a part of a flexible substrate that supports the plurality of light-emitting device units 10.

After the gap between the plurality of light-emitting device units 10 is enlarged by expanding the expandable film 510, the plurality of light-emitting device units 10 may be transferred to another supporting substrate while the gap is maintained. Since the expandable film 510 is expanded by the above-described expansion step such that the plurality of light-emitting device units 10 have a desired gap therebetween, the positioning step over the supporting substrate is greatly simplified, and the plurality of light-emitting device units 10 can be mounted at one time to another supporting substrate.

<Supporting Substrate>

The support member 520, which is a constituent of the supporting substrate 500, can be made of glass, plastic, or metal. The expandable film 510 can be realized by a resin film such as, for example, PVC (polyvinyl chloride), PET (polyethylene terephthalate), or PP (polypropylene), as are known dicing tapes. The expandable film 510 is made of, for example, a material which can be drawn out in in-plane directions in the presence of applied heat. The adhesive layer provided at the surface of the expandable film 510 may be made of an adhesive agent whose adhesive force decreases or disappears when irradiated with ultraviolet light. When such an adhesive layer is used, in removing the expandable film 510, the expandable film 510 can be easily delaminated by irradiating the adhesive layer with ultraviolet light. The adhesive layer provided at the surface of the expandable film 510 may be made of an adhesive agent whose adhesive force is unlikely to decrease even when irradiated with ultraviolet light. When the expandable film 510 used includes such an adhesive layer, in delaminating the crystal growth substrate 100 by a laser lift-off method, irradiation of the interface between the crystal growth substrate 100 and the frontplane 200 with ultraviolet light via the expandable film 510 enables the expandable film 510 and the crystal growth substrate 100 to be delaminated together without decreasing the adhesive force between the expandable film 510 and the crystal growth substrate 100.

In a form where the supporting substrate 500 does not include the expandable film 510, an unshown sticky layer is formed at the surface of the supporting substrate 500 and firmly attached to the frontplane 200.

In the example of FIG. 1A, when light radiated from a μLED of the frontplane 200 is extracted from the supporting substrate 500 (the light is extracted in the positive direction of Z axis), the supporting substrate 500 is made of a material which is capable of transmitting that light. Note that, however, when the light is extracted in the negative direction of Z axis, the supporting substrate 500 does not need to be capable of transmitting light. It is only necessary that the protecting film 540 or a film which has a touch sensor function is capable of transmitting light.

Note that, in the example of FIG. 1A, the supporting substrate 500 is provided on the backplane 400 side and secured to the backplane 400, although the embodiments of the present disclosure are not limited to such an example. Between the supporting substrate 500 and the backplane 400, an optical element such as lens sheet, diffuser sheet, or etc., and/or an electric/electronic circuit or a circuit element may be provided. The supporting substrate 500 may be provided on the frontplane 200 side. In that case, the aforementioned optical element or circuit element may be provided between the supporting substrate 500 and the frontplane 200. Still alternatively, two supporting substrates may be directly or indirectly secured to the frontplane 200 and the backplane 400, respectively.

The supporting substrate 500 may be realized by a flexible film. Typical examples of such a film include single-layer or multilayer films of polyethylene naphthalate (PEN), polyethylene terephthalate (PET), and polyimide (PI). The other examples than the flexible film can include metal foil.

In an embodiment of the present disclosure, the supporting substrate 500 includes interconnections which are to be coupled with electric circuits included in the backplane 400. By the interconnections, the light-emitting device units 10 are electrically coupled with one another. The thus-configured supporting substrate 500 can perform the function as a printed circuit board. A surface of the supporting substrate 500 which is oriented in the negative direction of Z axis may be provided with an unshown circuit element. When the supporting substrate 500 has a circuit pattern, the supporting substrate 500 and the backplane 400 can be adhered via an anisotropic electrically-conductive film. In this case, a portion (connecting portion) of the interconnection layer that is a constituent of the circuit pattern on the supporting substrate 500 is configured to have a greater thickness than the surroundings, whereby a connection which is necessary between the connecting portion of the interconnection layer and the electric circuit of the backplane can be realized at a predetermined position.

The material and thickness of the support member 520 included in the supporting substrate 500 can be arbitrarily selected according to its use. When the μLED device 1000 is used as, for example, a flexible display, the supporting substrate 500 can be realized by a multilayer film which has flexibility. In that case, it is necessary to curve or bend the frontplane 200, the middle layer 300 and the backplane 400 according to the deformation of the supporting substrate 500. Specifically, in the frontplane 200, for respective ones of the light-emitting device units 10 including one or a plurality of μLEDs, the space 530 can include an elastic material or air such that it can be inclined at some angle.

Since in the present disclosure the frontplane 200, the middle layer 300 and the backplane 400 are sequentially formed on the crystal growth substrate, these components are described in detail in the following paragraphs sequentially from the crystal growth substrate.

Firstly, refer to FIG. 1C. FIG. 1C is a cross-sectional view showing part of the μLED device 1000 of the present disclosure in the middle of the production process. The μLED device 1000 in a state shown in FIG. 1C still includes the crystal growth substrate 100. On a crystal growth substrate 100, a frontplane 200, a middle layer 300, and a backplane 400 are provided. The configuration of the frontplane 200, the middle layer 300, and the backplane 400 in FIG. 1C is substantially identical with the configuration of the frontplane 200, the middle layer 300, and the backplane 400 in FIG. 1A except that it is shown upside down. Note that, in the present disclosure, for the sake of convenience, a μLED device supported by the crystal growth substrate 100, which is in the middle of the production process, is designated by the same reference numeral as that of a μLED device which has passed through the production process (e.g., “1000”).

<Crystal Growth Substrate>

The crystal growth substrate 100 is a substrate on which semiconductor crystals, which are constituents of the μLEDs, are to epitaxially grow. A surface 100T of the crystal growth substrate 100 on which epitaxial crystal growth occurs is referred to as “upper surface” or “crystal growth surface”. Another surface 100B of the crystal growth substrate 100 which is opposite to the surface 100T is referred to as “lower surface”. In this specification, the terms “upper surface” and “lower surface” do not depend on the actual orientation of the substrate 100 when they are used.

A typical example of semiconductor crystals which can be used in embodiments of the present disclosure is a gallium nitride based compound semiconductor. Hereinafter, the gallium nitride based compound semiconductor is also referred to as “GaN”. Some of gallium (Ga) atoms in GaN may be substituted with aluminum (Al) atoms or indium (In) atoms. GaN in which some of Ga atoms are substituted with Al atoms is also referred to as “AlGaN”. GaN in which some of Ga atoms are substituted with In atoms is also referred to as “InGaN”. GaN in which some of Ga atoms are substituted with Al atoms and In atoms is also referred to as “AlInGaN” or “InAlGaN”. The bandgap of GaN is smaller than the bandgap of AlGaN but greater than the bandgap of InGaN. In the present disclosure, gallium nitride based compound semiconductors in which some of constituent atoms are substituted with other atoms are also generically referred to as “GaN”. “GaN” can be doped with an n-type impurity and/or a p-type impurity as impurity ion. GaN whose conductivity type is n-type is referred to as “n-GaN”. GaN whose conductivity type is p-type is referred to as “p-GaN”. Details of the method of epitaxial growing semiconductor crystals will be described later. In the embodiments of the present disclosure, semiconductor crystals which are constituents of the μLED are not limited to GaN-based semiconductors but may be made of a nitride semiconductor such as AlN, InN, or AlInN, or, any other type of semiconductor.

Examples of the crystal growth substrate 100 include sapphire substrates, GaN substrates, SiC substrates, and Si substrates. In an embodiment of the present disclosure, the crystal growth substrate 100 is not a constituent of a final μLED device 1000. The thickness of the crystal growth substrate 100 can be, for example, not less than 30 μm and not more than 1000 μm, preferably not more than 500 μm. Since the role of the crystal growth substrate 100 is the base for crystal growth, the rigidity of the final μLED device 1000 is reinforced by the supporting substrate 500. Note that, however, as previously described, the crystal growth substrate 100 may be divided for respective ones of the light-emitting device units 10 and kept firmly attached to corresponding light-emitting device units 10.

A typical example of the crystal growth substrate 100 is a sapphire substrate. If the crystal growth substrate 100 is made of sapphire, it is easy to delaminate the frontplane 200 from the crystal growth substrate 100 using a laser lift-off technique with ultraviolet light at a short wavelength. Note that, however, other delamination techniques may be used. In that case, the material of the crystal growth substrate 100 is not limited to sapphire.

The upper surface (crystal growth surface) 100T of the crystal growth substrate 100 may have a structure for relieving the crystal lattice mismatch, such as grooves or ridges. Also, a buffer layer for reducing the crystal lattice mismatch may be provided at the upper surface 100T of the crystal growth substrate 100.

In the present disclosure, the positive direction of Z axis shown in FIG. 1C (the direction of the arrow) is also referred to as “crystal growth direction” or “semiconductor layering direction”. The lower surface 100B and the upper surface 100T of the crystal growth substrate 100 may be referred to as “front surface” and “rear surface”, respectively, of the crystal growth substrate 100.

<Frontplane>

The frontplane 200 includes a plurality of μLEDs 220 and a device isolation region 240 located between the plurality of μLEDs 220. The plurality of μLEDs 220 can be arrayed, in the middle of the production process, in rows and columns in a two-dimensional plane (XY plane) which is parallel to the upper surface 100T of the crystal growth substrate 100. Each of the plurality of μLEDs 220 includes a first semiconductor layer 21 of the first conductivity type and a second semiconductor layer 22 of the second conductivity type as shown in FIG. 1C. The second semiconductor layer 22 is closer to the crystal growth substrate 100 than the first semiconductor layer 21.

In an embodiment of the present disclosure, each of the μLEDs 220 includes an emission layer 23 which can emit light independently of the other μLEDs 220. The emission layer 23 is present between the first semiconductor layer 21 and the second semiconductor layer 22. The device isolation region 240 includes at least one metal plug 24 electrically coupled with the second semiconductor layer 22. The metal plug 24 functions as a substrate-side electrode of the μLEDs 220.

A typical example of the first semiconductor layer of the first conductivity type is a p-GaN layer. A typical example of the second semiconductor layer 22 of the second conductivity type is an n-GaN layer. Each of the p-GaN layer and the n-GaN layer does not need to have a homogeneous composition along a direction perpendicular to the upper surface 100T of the substrate 100 (semiconductor layering direction: positive direction of Z axis) but can have a multilayer structure. As previously described, Ga of GaN can be at least partially substituted with Al and/or In. Such substitution can be carried out for adjusting the bandgap and/or the refractive index of GaN. The concentration of the n-type impurity and the p-type impurity, i.e., the doping level, also does not need to be constant along the semiconductor layering direction (positive direction of Z axis).

A typical example of the emission layer 23 include at least one InGaN well layer. When the emission layer 23 includes a plurality of InGaN well layers, a GaN barrier layer or an AlGaN barrier layer, which has a greater bandgap than the InGaN well layer, can be provided between the respective InGaN well layers. The InGaN well layer and the AlGaN barrier layer may be an InAlGaN well layer and an InAlGaN barrier layer, respectively. The bandgap of the InGaN well layer defines the emission wavelength. Specifically, λ×Eg=1240 holds where Δ [nm] is the emission wavelength in vacuum and Eg [electron volt: eV] is the bandgap. Therefore, for example, blue light at A=450 nm can be radiated by adjusting the bandgap Eg of the InGaN well layer to about 2.76 eV. The bandgap of the InGaN well layer can be adjusted according to the In molar fraction in the InGaN well layer. When an InAlGaN well layer is used, the bandgap can be adjusted likewise according to the In molar fraction and the Al molar fraction. The In molar fraction in the InGaN well layer epitaxially grown on the crystal growth substrate 100 has a generally equal value across the entire surface of the crystal growth substrate 100. Thus, a plurality of μLEDs 220 provided on the same crystal growth substrate 100 can radiate light at generally equal wavelengths.

Each of the plurality of semiconductor layers which are constituents of each μLED 220 is a monocrystalline layer epitaxially grown on the crystal growth substrate 100 (epitaxial layer). The device isolation region 240 is defined by a trench-like recessed portion (hereinafter, referred to as “trench”) which is formed by partially etching the plurality of semiconductor layers epitaxially grown on the crystal growth substrate 100. The occupation region of each of the μLEDs 220 isolated by the trench has a size which can be included within an area of 100 μm×100 μm (e.g., area of 10 μm×10 μm). The occupation region of the μLED 220 is defined by the contour of the first semiconductor layer 21 defined by the device isolation region 240.

As shown in FIG. 1B, the device isolation region 240 surrounds each of the μLEDs 220 and isolates each of the μLEDs 220 from the other μLEDs 220. More specifically, the device isolation region 240 electrically and spatially isolate the first semiconductor layer 21 and the emission layer 23 of each of the μLEDs 220 from the first semiconductor layer 21 and the emission layer 23 of the other μLEDs 220.

As shown in FIG. 1C, the second semiconductor layer 22 in the middle of the production process does not need to be completely isolated in each of the μLEDs 220. In the example shown in FIG. 1C, the second semiconductor layer 22 included in respective ones of the plurality of μLEDs 220 is formed by a single continuous semiconductor layer and is shared among the plurality of μLEDs 220.

The number of μLEDs 220 included in the light-emitting device units 10 is not limited to one but may be plural. For example, respective ones of the light-emitting device units 10 may form sub-pixels of different colors such as R, G, and B. Still alternatively, a single light-emitting device unit 10 may have such a shape that a plurality of sub-pixels of the same color (e.g., any of RGB) are arrayed in a straight or bent line. In the attached drawings, for the sake of simplicity, each of the divided light-emitting device units 10 is illustrated as including a single μLED 220. However, one or a plurality of μLEDs 220 can be included in each of the light-emitting device units 10.

When, in each of the light-emitting device units 10 after having been divided, the single continuous second semiconductor layer 22 is shared among the plurality of μLEDs 220, this second semiconductor layer 22 functions as a common electrode on the second conductivity side for the plurality of μLEDs 220. In each of the light-emitting device units 10 after having been divided, the second semiconductor layer 22 of each of the μLEDs 220 may be isolated from the second semiconductor layers 22 of the other μLEDs 220 so long as it is appropriately coupled with a metal plug 24 or a TiN buffer layer which will be described later.

In this example, the device isolation region 240 includes an embedded insulator 25 which fills the gap between the plurality of μLEDs 220. The embedded insulator 25 has one or a plurality of through holes for the metal plugs 24. The through holes are filled with the metal material which forms the metal plugs 24. The metal plugs 24 may have a structure formed by stacking layers of different metals.

In the example shown in FIG. 1B, a plurality of metal plugs 24 are discretely arranged, although embodiments of the present disclosure are not limited to such an example. Each of the plurality of metal plugs 24 may have a ring-like shape surrounding a corresponding one of the μLEDs 220. The metal plugs 24 may have the shape of stripes extending in parallel in one direction as shown in FIG. 1E or may be a single conductor which has the shape of a lattice as shown in FIG. 1F.

The metal plug 24 does not transmit light. Therefore, when the metal plug 24 has a shape which surrounds each of the μLEDs 220 (for example, when the metal plug 24 has the shape of FIG. 1F), the metal plug 24 produces the effect of preventing light radiated from each of the μLEDs 220 from being mixed with light radiated from the other μLEDs 220. Instead of the function of the metal plug 24 as such a light-blocking member, a light-blocking member surrounding each of the μLEDs 220 may be additionally provided in the device isolation region 240. In this way, the device isolation region 240 may have an additional function of optically isolating the emission layer 23 of each of the μLEDs 220 from the emission layers 23 of the other μLEDs 220.

In an embodiment of the present disclosure, the upper surface of the frontplane 200 is preferably planarized as shown in FIG. 1C. Such planarization is realized by making the level of the upper surfaces of the metal plug 24 and the embedded insulator 25 in the device isolation region 240 generally coincident with the level of the upper surface of the first semiconductor layer 21 in the μLEDs 220.

<Middle Layer>

The middle layer 300 includes a plurality of first contact electrodes 31 and second contact electrodes 32 (see FIG. 1C). The plurality of first contact electrodes 31 are, respectively, electrically coupled with the first semiconductor layers 21 of the plurality of μLEDs 220. At least one second contact electrode 32 is coupled with the metal plug 24.

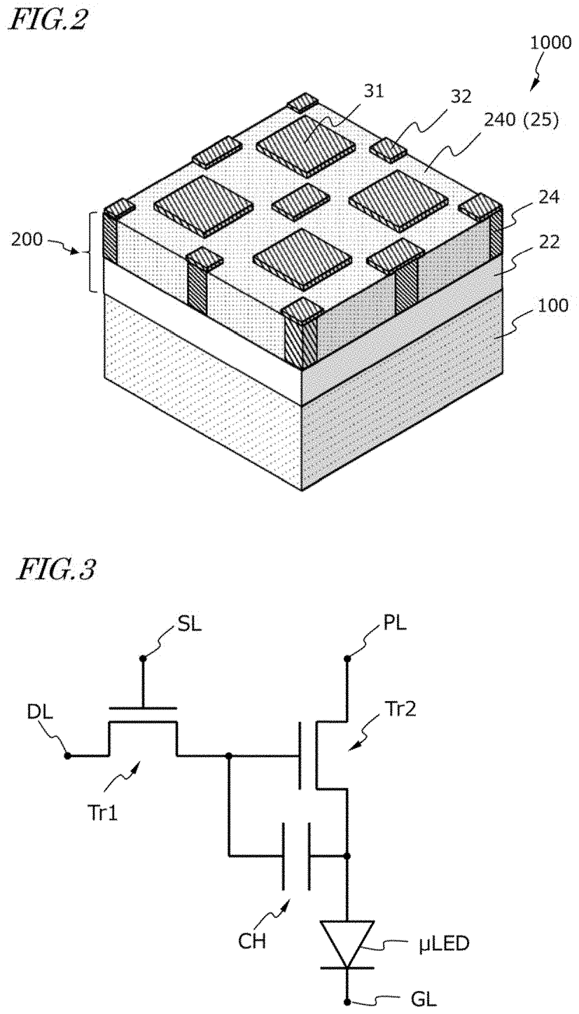

FIG. 2 is a perspective view showing an arrangement example of the first contact electrodes 31 and the second contact electrodes 32 in a phase where the middle layer 300 has been formed in the production process. The structure shown in FIG. 2 is merely a part of the μLED device 1000. As previously described, an embodiment of the μLED device 1000 includes a large number of μLEDs 220. The structure shown in FIG. 2 may be finally divided such that respective divisional pieces belong to different light-emitting device units 10 or included in a single light-emitting device unit 10.

The second contact electrodes 32 shown in FIG. 2 are electrically coupled with the second semiconductor layer 22 via the metal plugs 24. The shape and size of the second contact electrodes 32 are not limited to the example shown in the drawing. Since the metal plugs 24 can have various shapes as previously described, the flexibility in arrangement of the second contact electrodes 32 is high so long as they are electrically coupled with the second semiconductor layer 22 via the metal plugs 24. Meanwhile, respective ones of the first contact electrodes 31 are independently electrically coupled with the first semiconductor layers 21 of the plurality of μLEDs 220. When viewed in a direction perpendicular to the upper surface 100T of the crystal growth substrate 100, the shape and size of the first contact electrodes 31 do not need to be identical with the shape and size of the first semiconductor layers 21.

Since the upper surface of the frontplane 200 is planarized as previously described, the distances from the crystal growth substrate 100 to the first contact electrodes 31 and the second contact electrodes 32, in other words, the “heights” or “levels” of the contact electrodes 31, 32, are mutually equal. This feature facilitates formation of the backplane 400 (described later) with the use of a semiconductor manufacture technique. In the present disclosure, the “semiconductor manufacture technique” includes the process of depositing a thin film of a semiconductor, insulator, or conductor and the process of patterning the thin film by lithography and etching. In this specification, a “planarized surface” means a surface at which the level difference caused by raised or recessed portions at the surface is not more than 300 nm. In a preferred embodiment, this level difference is not more than 100 nm.

Refer again to FIG. 1C. In the example shown in FIG. 1C, the middle layer 300 includes an interlayer insulating layer 38 which has a flat surface. The interlayer insulating layer 38 has a plurality of contact holes for respectively coupling the first and second contact electrodes 31, 32 with the electric circuit of the backplane 400. The contact holes are filled with via electrodes 36.

In an embodiment of the present disclosure, it is preferred to planarize the upper surface of the interlayer insulating layer 38 prior to formation of the backplane 400. In planarizing the insulating layer prior to, or in the middle of, formation of the backplane 400, chemical mechanical polishing (CMP) can be preferably used instead of etch back.

<Backplane>

The backplane 400 includes an electric circuit which is not shown in FIG. 1C. The electric circuit is electrically coupled with the plurality of μLEDs 220 via the plurality of first contact electrodes 31 and at least one second contact electrode 32. The electric circuit includes a plurality of thin film transistors (TFTs) and other circuit components. As will be described later, each of the TFTs includes a semiconductor layer deposited on the frontplane 200 supported by the crystal growth substrate 100 and/or on the middle layer 300.

FIG. 3 is a basic equivalent circuit diagram of a sub-pixel in a case where the μLED device 1000 functions as a display device. A single pixel of the display device can include sub-pixels of different colors, for example, R, G, and B. In the example shown in FIG. 3, the electric circuit of the backplane 400 includes a selection TFT element Tr1, a driving TFT element Tr2, and a holding capacitance CH. The μLED shown in FIG. 3 is present in the frontplane 200 rather than the backplane 400.

In the example of FIG. 3, the selection TFT element Tr1 is coupled with a data line DL and a selection line SL. The data line DL is an interconnection for carrying data signals which define images to be displayed. The data line DL is electrically coupled with the gate of the driving TFT element Tr2 via the selection TFT element Tr1. The selection line SL is an interconnection for carrying signals which control the ON/OFF of the selection TFT element Tr1. The driving TFT element Tr2 controls the state of conduction between a power line PL and the μLED. When the driving TFT element Tr2 is ON, an electric current flows from the power line PL to the ground line GL via the μLED. This electric current causes the μLED to emit light. If the selection TFT element Tr1 is turned OFF, the ON state of the driving TFT element Tr2 is maintained by the holding capacitance CH.

The electric circuit of the backplane 400 can include the selection TFT element Tr1, the driving TFT element Tr2, the data line DL, the selection line SL, and other elements, although the configuration of the electric circuit is not limited to such an example.

The μLED device 1000 of the present embodiment can solely function as a display device, although a display device of a larger display area may be realized by tiling with a plurality of μLED devices 1000.

<Production Method>

Next, a basic example of the method of producing the PLED device 1000 is described.

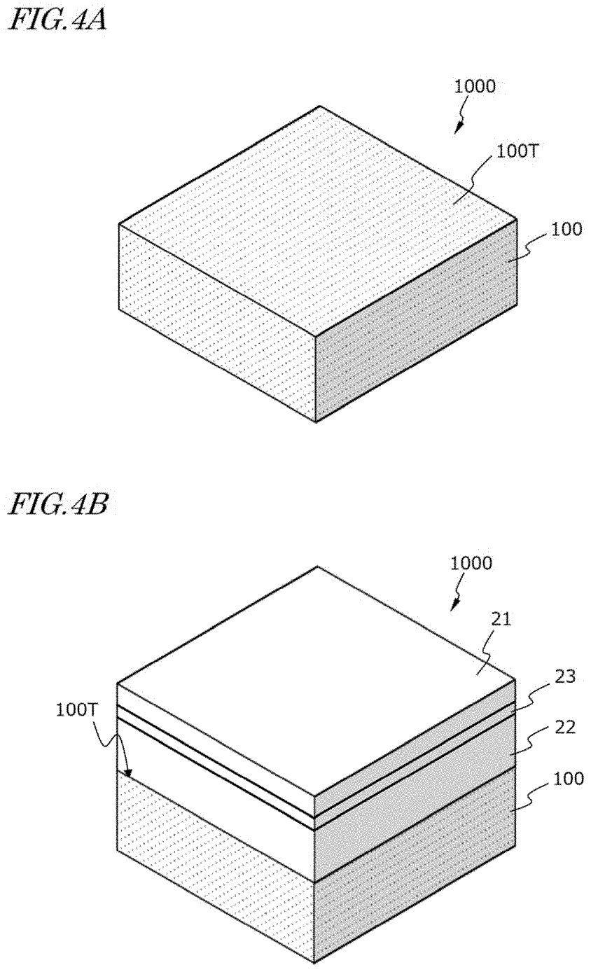

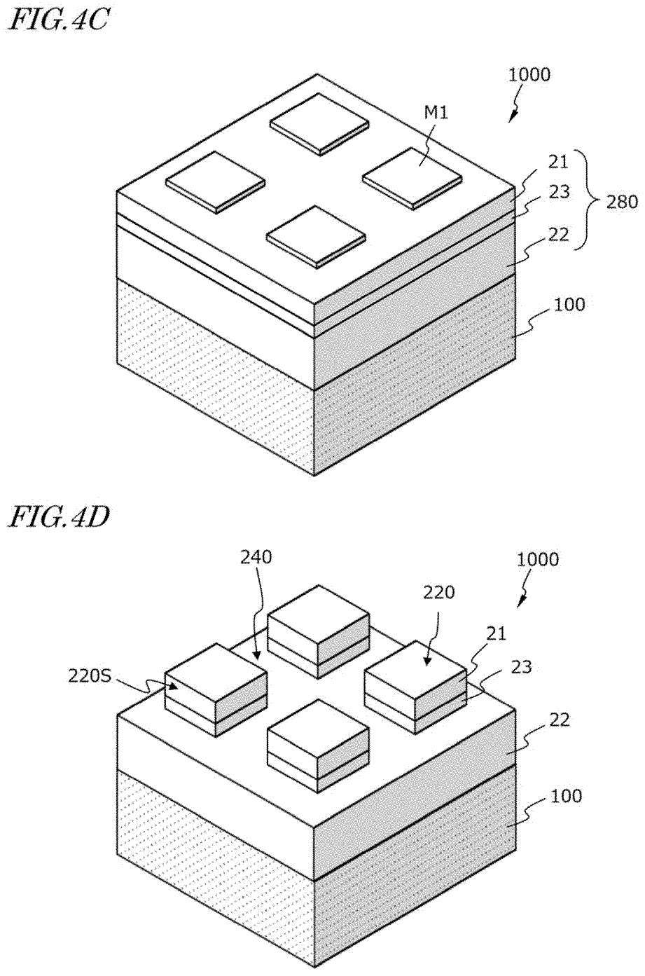

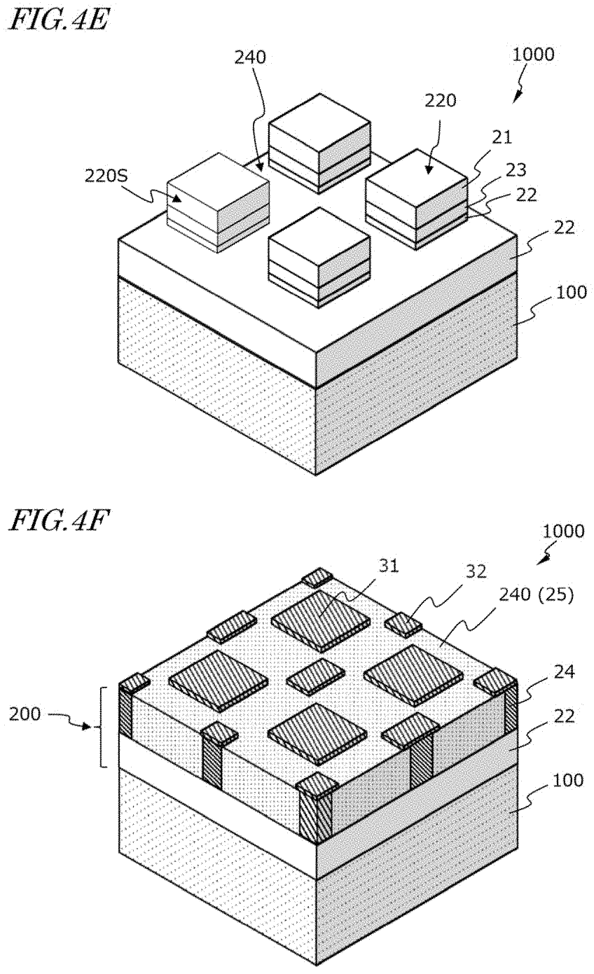

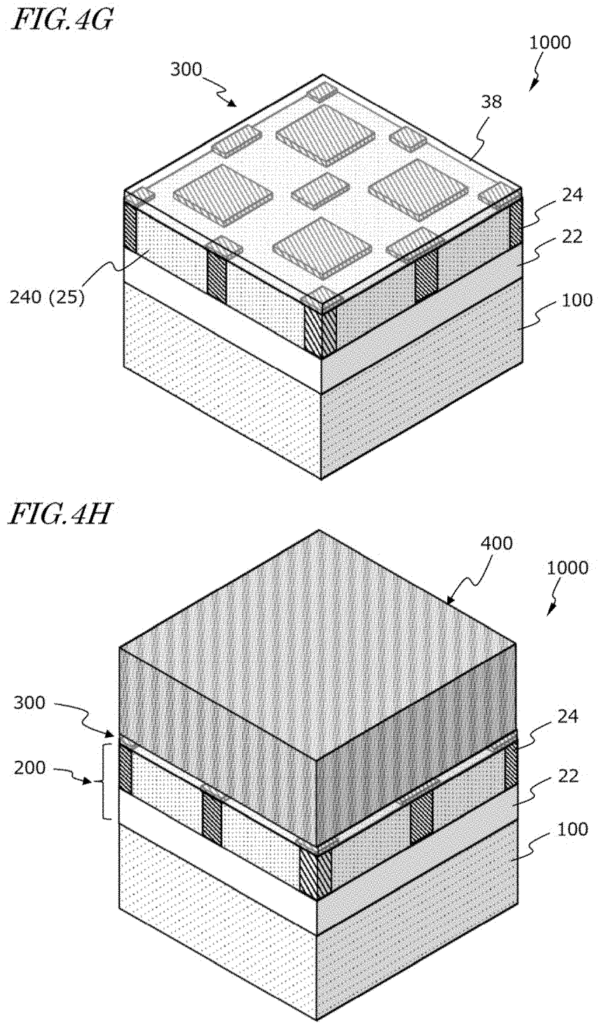

Firstly, as shown in FIG. 4A, a crystal growth substrate 100 is provided which has an upper surface (crystal growth surface) 100T. FIG. 4A shows only a part of the crystal growth substrate 100 extending across a plane which is parallel to the upper surface 100T.

As shown in FIG. 4B, a plurality of semiconductor layers, including a second semiconductor layer 22 of the second conductivity type, an emission layer 23, and a first semiconductor layer 21 of the first conductivity type, are epitaxially grown from the upper surface 100T of the crystal growth substrate 100. Each of the semiconductor layers is a monocrystalline epitaxially-grown layer of a gallium nitride based compound semiconductor. The epitaxial growth of the gallium nitride based compound semiconductor can be carried out by, for example, MOCVD (Metal Organic Chemical Vapor Deposition). Impurities which define each conductivity type can be introduced for doping from a gaseous phase during the crystal growth.

After a semiconductor multilayer structure 280 which includes the above-described semiconductor layers is formed on the crystal growth substrate 100, a mask M1 is formed on the first semiconductor layer 21 as shown in FIG. 4C. The mask M1 has an opening which defines the shape and position of the device isolation region 240. In other words, the mask M1 defines the shape and position of the μLEDs 220. Part of the semiconductor multilayer structure 280 which is not covered with the mask M1 is etched from the upper surface, whereby a trench which defines the device isolation region 240 is formed as shown in FIG. 4D. This etching (mesa etching) can be carried out by, for example, inductively coupled plasma (ICP) etching or reactive ion etching (RIE). The depth of the etching is determined such that the second semiconductor layer 22 appears at the bottom of the trench. The depth of the trench formed by etching can be, for example, not less than 0.5 μm and not more than 5 μm. The width of the trench can be, for example, not less than 5 μm and not more than 100 μm. The transverse dimension of each of the μLEDs 220 can be, for example, not less than 5 μm and not more than 100 μm, typically 15 μm. Side surfaces 2205 of the μLEDs 220 are exposed by etching. In other words, each of the μLEDs 220 has etched side surfaces 2205. FIG. 4E schematically shows a state of the second semiconductor layer 22 where a portion near the upper surface has been etched away.

Then, after the device isolation region 240 is formed, first contact electrodes 31 and second contact electrodes 32 are formed as shown in FIG. 4F. In this example, the device isolation region 240 includes an embedded insulator 25 and a plurality of metal plugs 24 provided in a plurality of through holes of the embedded insulator 25.

After an interlayer insulating layer 38 (thickness: for example, 500 nm to 1500 nm) of the middle layer 300 is formed as shown in FIG. 4G, a plurality of contact holes (not shown in FIG. 4G) are formed in the interlayer insulating layer 38 for coupling the electric circuit of the backplane 400 with the μLEDs 220 of the frontplane 200. The contact holes are formed so as to reach the contact electrodes 31, 32 which are present in the underlying layer. The contact holes are filled with via electrodes. The upper surface of the interlayer insulating layer 38 can be planarized by CMP.

As shown in FIG. 4H, a backplane 400 is formed on the middle layer 300. A characteristic feature of the present disclosure resides in that various electronic elements and interconnections which are constituents of the backplane 400 are directly formed by a semiconductor manufacture technique on a multilayer stack which includes the frontplane 200 and the middle layer 300, rather than adhering the backplane 400 onto the middle layer 300. As a result, each of a plurality of TFTs included in the backplane 400 includes semiconductor layers deposited on the multilayer stack that includes the frontplane 200 supported by the crystal growth substrate 100 and the middle layer 300.

As previously described, when the upper surface of the frontplane 200 and the upper surface of the middle layer 300 are planarized, it is easy to produce the backplane 400 which includes the TFTs by a semiconductor manufacture technique. In general, when TFTs are formed by a semiconductor manufacture technique, it is necessary to perform patterning of deposited semiconductor layers, insulating layers, and metal layers. The patterning is realized by a lithography process which involves exposure to light. If there is a large step in the underlayer of the deposited semiconductor layers, insulating layers, and metal layers, light will not be correctly focused in the exposure so that micropatterning with high precision cannot be realized. In an embodiment of the present disclosure, the entirety of the frontplane 200 including the device isolation region 240 is planarized and, accordingly, the middle layer 300 is also planarized, so that it is easy to form the backplane 400 by a semiconductor manufacture technique.

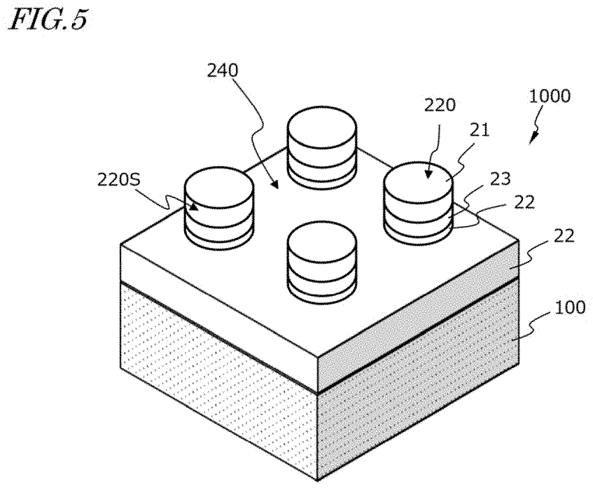

In the above-described example, the shape of the μLEDs 220 is generally rectangular parallelepipedic, although the shape of the μLEDs 220 may be the shape of a cylindrical pillar as shown in FIG. 5, a polygonal pillar such as hexagonal pillar, or an elliptical pillar. FIG. 5 is a perspective view showing part of the μLED device which includes μLEDs 220 in the shape of a cylindrical pillar.

### Embodiment

Hereinafter, a basic embodiment of a μLED device of the present disclosure is described in more detail.

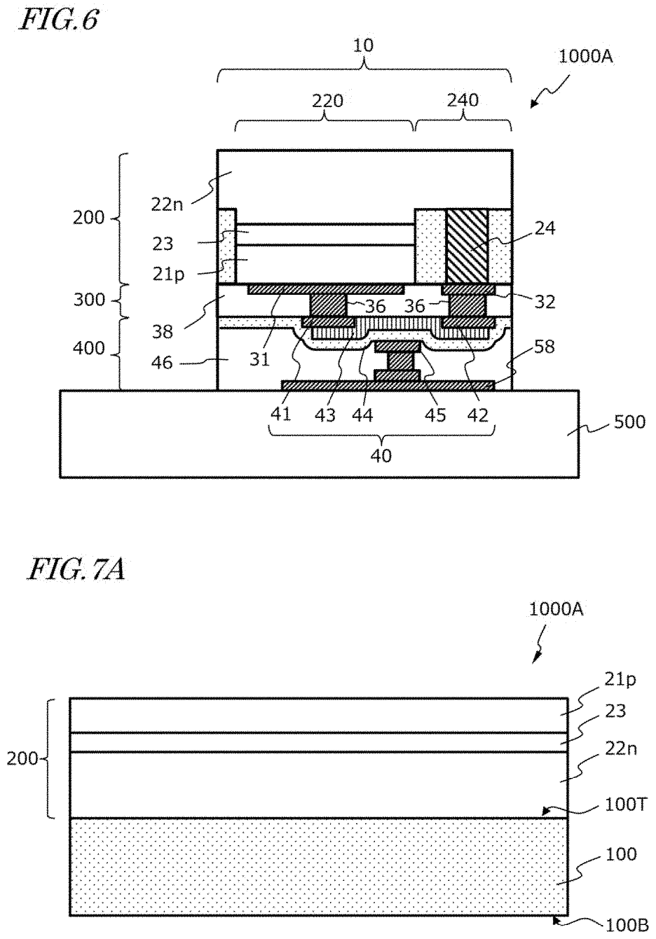

Refer to FIG. 6. FIG. 6 is a cross-sectional view schematically showing a configuration of a single light-emitting device unit 10 included in a μLED device 1000A of the present embodiment. The μLED device 1000A of the present embodiment is a display device which has the same configuration as the previously-described basic configuration example. The μLED device 1000A includes a frontplane 200, a middle layer 300 provided on the frontplane 200, a backplane 400 provided on the middle layer 300, and a supporting substrate 500 which supports these components. The supporting substrate 500 includes an interconnection 58 that couples the light-emitting device unit 10 with an adjoining light-emitting device unit, a circuit such as an unshown driver, and/or a power supply.

In the example shown in the drawing, a single light-emitting device unit 10 includes a single μLED 220 and a device isolation region 240 provided around the μLED 220, although the embodiments of the present disclosure are not limited to this example. Each of the light-emitting device units 10 may include a plurality of μLEDs 220 and a device isolation region 240 which isolates the plurality of μLEDs 220.

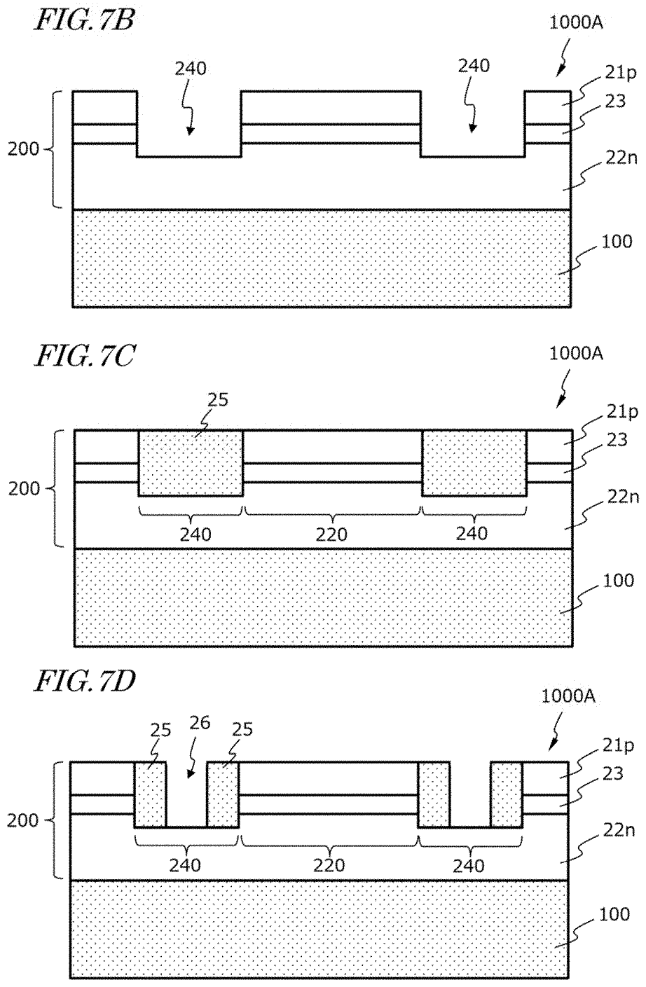

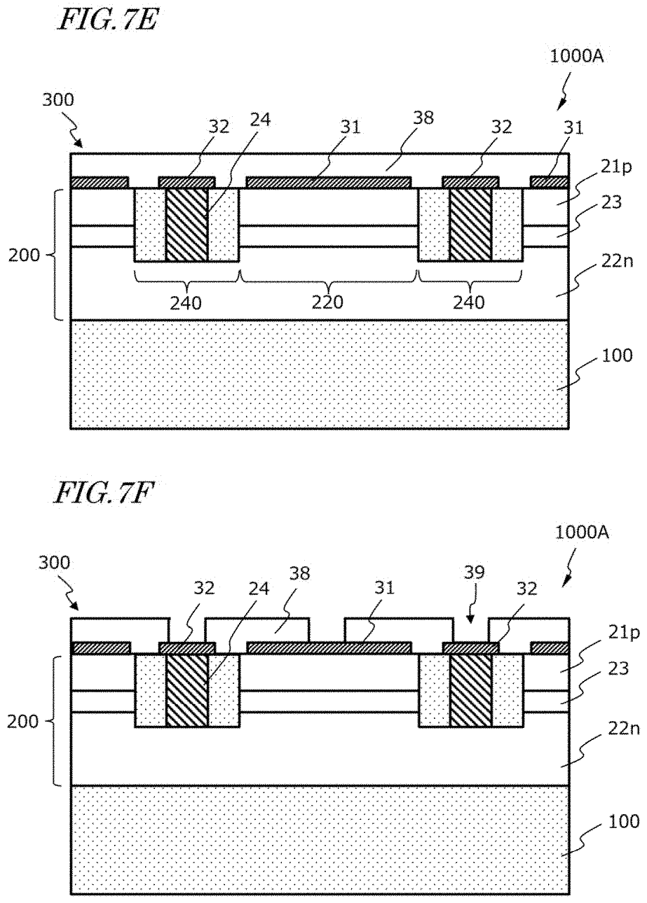

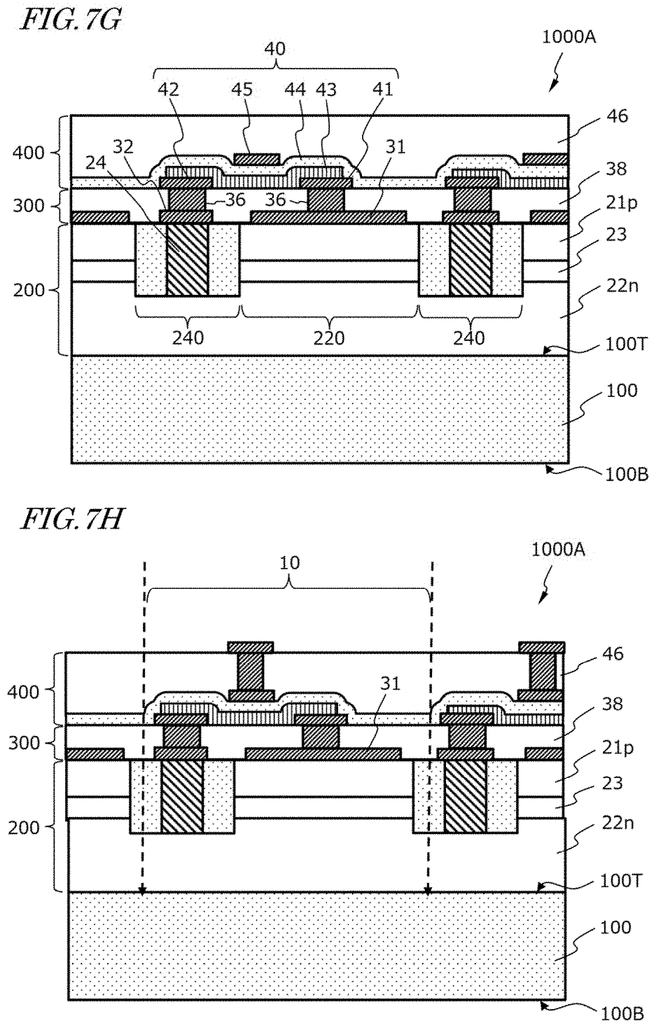

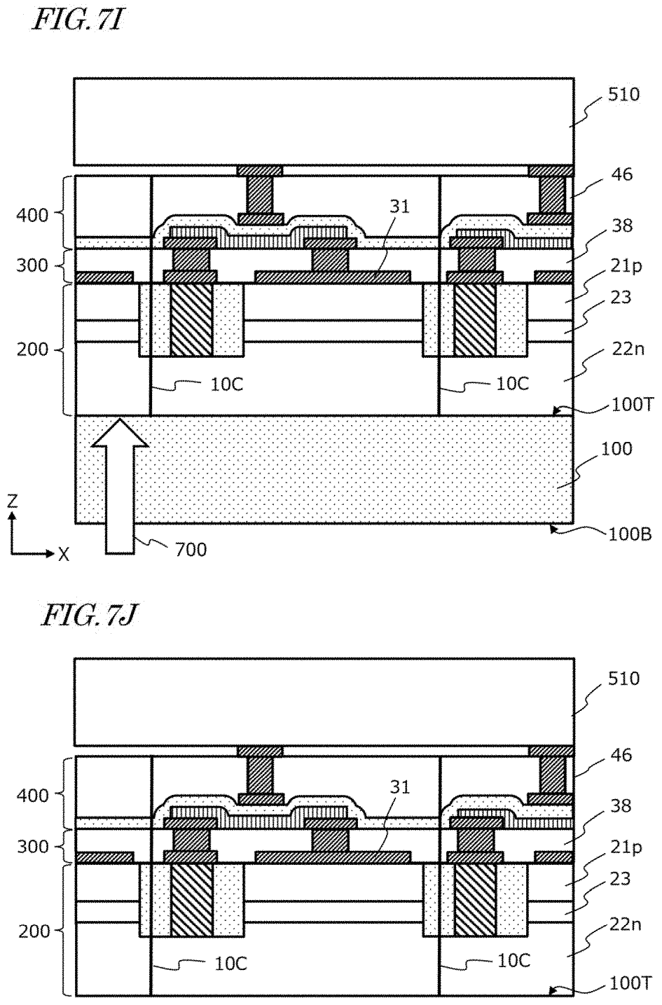

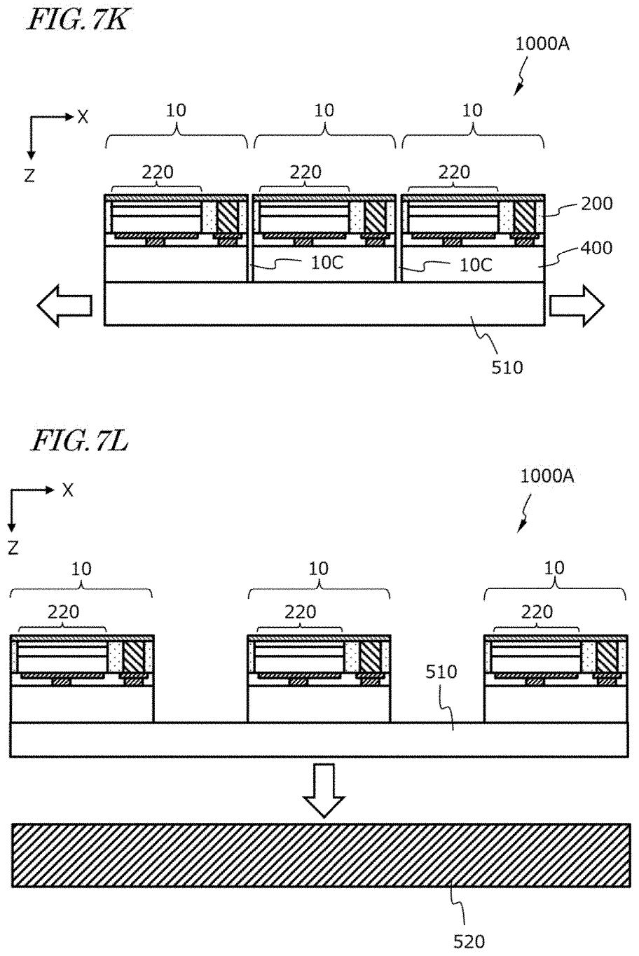

Next, an example of the configuration and production method of the μLED device 1000A of the present embodiment is described with reference to FIG. 7A through FIG. 9.

First, refer to FIG. 7A. In the present embodiment, a crystal growth substrate 100 is placed in a reactor of a MOCVD apparatus, and various gases are supplied into the reactor for carrying out epitaxial growth of a gallium nitride (GaN) based compound semiconductor. In the present embodiment, the crystal growth substrate 100 is a sapphire substrate whose thickness is, for example, about 50-600 μm. The upper surface 100T of the crystal growth substrate 100 is typically a C-plane (0001), although the crystal growth substrate 100 may have a nonpolar or semipolar plane, such as m-plane, a-plane, or r-plane, at the upper surface. The upper surface 100T may be inclined by about several degrees from these crystal planes. The crystal growth substrate 100 typically has the shape of a circular plate. The diameter of the crystal growth substrate 100 can be, for example, from 1 inch to 8 inches. The shape and size of the crystal growth substrate 100 are not limited to this example. The crystal growth substrate 100 may have a rectangular shape. The production process may be carried on using a crystal growth substrate 100 in the shape of a circular plate, and the crystal growth substrate 100 may be processed into a rectangular shape by cutting away peripheral parts of the crystal growth substrate 100 in the final steps. Alternatively, the production process may be carried on using a relatively-large crystal growth substrate 100, and the single crystal growth substrate 100 may be divided into a plurality of μLED devices in the final steps (singulation).

Firstly, trimethyl gallium (TMG) or triethyl gallium (TEG), hydrogen (H₂) as the carrier gas, nitrogen (N₂), ammonia (NH₃), and silane (SiH₄) are supplied into the reactor of the MOCVD apparatus. The crystal growth substrate 100 is heated to about 1100° C., and an n-GaN layer 22n (thickness: for example, 2 μm) is epitaxially grown. Silane is a material gas for supplying Si as the n-type dopant. The doping concentration of the n-type impurity can be, for example, 5×10¹⁷ cm⁻³.

Then, supply of SiH₄ is stopped, the crystal growth substrate 100 is cooled to a temperature lower than 800° C., and an emission layer 23 is formed. Specifically, firstly, a GaN barrier layer is epitaxially grown. Further, supply of trimethyl indium (TMI) is started, and an In_{y}Ga_{1-y}N (0<y<1) well layer is epitaxially grown. The GaN barrier layer and the In_{y}Ga_{1-y}N (0<y<1) well layer are alternately epitaxially grown over two or more periods, whereby an emission layer 23 (thickness: for example, 100 nm), including a GaN/InGaN multi-quantum well which functions as the light-emitting part, can be formed. As the number of In_{y}Ga_{1-y}N (0<y<1) well layers is larger, the carrier density inside the well layers can be prevented from being excessively large in driving with a large electric current. A single emission layer 23 may include a single In_{y}Ga_{1-y}N (0<y<1) well layer interposed between two GaN barrier layers. An In_{y}Ga_{1-y}N (0<y<1) well layer may be directly formed on the n-GaN layer 22n, and a GaN barrier layer may be formed on the In_{y}Ga_{1-y}N (0<y<1) well layer. The In_{y}Ga_{1-y}N (0<y<1) well layer may include Al. For example, the In_{y}Ga_{1-y}N (0<y<1) well layer may be made of AlₓIn_{y}Ga_{z}N (0≤x<1, 0<y<1, 0<z<1).

After the emission layer 23 is formed, supply of TMI is once stopped. Thereafter, nitrogen is added to the carrier gas (hydrogen), supply of ammonia is resumed, the epitaxial growth temperature is increased to a temperature in the range of 850° C. to 1000° C., and trimethyl aluminum (TMA) and biscyclopentadienyl magnesium (Cp₂Mg) as the material for Mg as the p-type dopant are supplied, whereby a p-AlGaN overflow suppression layer may be epitaxially grown. Then, supply of TMA is stopped, and a p-GaN layer 21p (thickness: for example, 0.5 μm) is epitaxially grown. The doping concentration of the p-type impurity can be, for example, 5×10¹⁷ cm⁻³.

Then, as shown in FIG. 7B, photolithography and etching are performed on the crystal growth substrate 100 pulled out of the reactor of the MOCVD apparatus, whereby predetermined regions of the p-GaN layer 21p and the emission layer 23 (portions in which the device isolation region 240 is to be formed; Depth: for example, 1.5 μm) are removed such that the n-GaN layer 22n is partially exposed. Etching of the gallium nitride based semiconductor can be carried out using a plasma of a chloric gas as will be described later.

As shown in FIG. 7C, the spaces that define the device isolation region 240 are filled with the embedded insulator 25. The material and formation method of the embedded insulator 25 are arbitrary. In the example shown in the drawing, the upper surface of the embedded insulator 25 is planarized and located at the same level as the upper surface of the p-GaN layer 21p. In the present embodiment, a thermosetting resin is selectively dropped to the device isolation region 240 using an inkjet method and then left still for a while, whereby the surface is planarized. Thereafter, the resin is cured by heating.

As shown in FIG. 7D, through holes 26 are formed in part of the embedded insulator 25 so as to reach the n-GaN layer 22n. The through holes 26 define the position and shape of the metal plugs 24. The through holes 26 have, for example, a rectangular shape of 5 μm or longer on one side or a circular shape of 5 μm or longer in diameter. The through holes 26 may have a shape which is capable of containing the metal plugs 24 which have such a shape as shown in, for example, FIG. 1E and FIG. 1F.

As shown in FIG. 7E, metal plugs 24 are formed so as to fill the through holes 26, and the upper surface of the frontplane 200 is planarized. Thereafter, first contact electrodes 31 and second contact electrodes 32 are formed. The planarization can be carried out through various processes such as, for example, etch back, selective growth, CMP, or lift-off.

The metal plugs 24 can be made of metal, for example, titanium (Ti) and/or aluminum (Al), such that an n-type ohmic contact with the n-GaN layer 22n can be established. The metal plugs 24 preferably include a metal layer which contains Ti in a portion in contact with the n-GaN layer 22n (e.g., TiN layer). The presence of the metal layer which contains Ti contributes to realization of a low-resistance ohmic contact with n-GaN or TiN. For example, the TiN layer can be formed by forming a Ti layer so as to be in contact with the n-GaN layer 22n and thereafter performing a heat treatment at, for example, about 600° C. for 30 seconds.

The first and second contact electrodes 31, 32 can be formed by deposition and patterning of a metal layer. Between the first contact electrodes 31 and the p-GaN layer 21p of the μLEDs 220, a metal-semiconductor interface is formed. To realize a p-type ohmic contact, the material of the first contact electrodes 31 can be selected from metals of large work function such as, for example, platinum (Pt) and/or palladium (Pd). After a layer of Pt or Pd (thickness: about 50 nm) is formed, a heat treatment can be performed at a temperature of, for example, not less than 350° C. and not more than 400° C. for about 30 seconds. So long as a layer of Pt or Pd is present in a portion which is in direct contact with the p-GaN layer 21p, a layer of a different metal, for example, a Ti layer (thickness: about 50 nm) and/or an Au layer (thickness: about 200 nm), may be formed on that layer.

In the upper part of the p-GaN layer 21p, a region doped with the p-type impurity at a relatively-high concentration may be formed. The second contact electrodes 32 are electrically coupled with the metal plugs 24 rather than the semiconductor. Therefore, the material of the second contact electrodes 32 can be selected from a wide range. The first contact electrodes 31 and the second contact electrodes 32 may be formed by patterning a single continuous metal layer. This patterning also includes lift-off. If the first contact electrodes 31 and the second contact electrodes 32 have equal thicknesses, connection with the electric circuit in the backplane 400, such as TFT 40 which will be described later, will be easy.

After the first and second contact electrodes 31, are formed, these electrodes are covered with an interlayer insulating layer 38 (thickness: for example, 1000 nm to 1500 nm). In a preferred example, the upper surface of the interlayer insulating layer 38 can be planarized by CMP or the like. The thickness of the interlayer insulating layer 38 that has the planarized upper surface means “average thickness”.

As shown in FIG. 7F, contact holes 39 are formed in the interlayer insulating layer 38. The contact holes 39 are used for electrically coupling the electric circuit of the backplane 400 with the μLEDs 220 of the frontplane 200.

Hereinafter, a configuration example and formation method of TFTs included in the electric circuit of the backplane 400 are described with reference to FIG. 7G.

In the example shown in FIG. 7G, the TFT 40 includes a drain electrode 41 and a source electrode 42 which are provided on the interlayer insulating layer 38, a semiconductor thin film 43 which is in contact with at least part of the upper surface of each of the drain electrode 41 and the source electrode 42, a gate insulating film 44 provided on the semiconductor thin film 43, and a gate electrode 45 provided on the gate insulating film 44. In the example shown in the drawing, the drain electrode 41 and the source electrode 42 are coupled with the first contact electrode 31 and the second contact electrode 32, respectively, via the via electrodes 36. These constituents of the TFT 40 are formed by a known semiconductor manufacture technique.

The semiconductor thin film 43 can be made of polycrystalline silicon, amorphous silicon, oxide semiconductor, and/or gallium nitride based semiconductor. The polycrystalline silicon can be formed by depositing amorphous silicon on the interlayer insulating layer 38 of the middle layer 300 by, for example, a thin film deposition technique and thereafter crystallizing the amorphous silicon with a laser beam. The thus-formed polycrystalline silicon is referred to as LTPS (Low-Temperature Poly Silicon). The polycrystalline silicon is patterned into a desired shape by lithography and etching.

In FIG. 7G, the TFT 40 is covered with an insulating layer 46 (thickness: for example, 500 nm to 3000 nm). The insulating layer 46 has an unshown hole which enables coupling of, for example, the gate electrode 45 of the TFT 40 with an external driver integrated circuit device or the like. Preferably, the upper surface of the insulating layer 46 is also planarized. The electric circuit of the backplane 400 can include circuit components such as unshown TFTs, capacitors, and diodes. Thus, the insulating layer 46 may have a configuration where a plurality of insulating layers are stacked up. In this case, each of the insulating layers can include a via electrode for coupling circuit components when necessary. On each of the insulating layers, interconnections can be formed when necessary.

In the present embodiment, the backplane 400 can have the same configuration as a known backplane (e.g., TFT substrate). Note that, however, the backplane 400 of the present disclosure is characterized in that it is formed on the μLEDs 220 in the underlying layer by a semiconductor manufacture technique. Therefore, for example, the drain electrode 41 and the source electrode 42 of the TFT 40 can be formed by patterning a metal layer which is deposited so as to cover the frontplane 200. Such patterning enables high-precision aligning which is based on lithography techniques. Particularly in the present embodiment, the frontplane 200 and/or the middle layer 300 are planarized and, therefore, it is possible to increase the resolution of the lithography. As a result, it is possible to produce a device which includes a large number of μLEDs 220 aligned at a microscopic pitch of for example not more than 20 μm, in an extreme example not more than 5 μm, at a high yield and at a low cost.

The configuration of the TFT 40 shown in FIG. 7G is exemplary. For the sake of clear description, in the example described herein, the drain electrode 41 of the TFT 40 is electrically coupled with the first contact electrode 31, although the drain electrode 41 of the TFT 40 may be coupled with any other circuit component or interconnection included in the backplane 400. The source electrode 42 of the TFT 40 does not need to be electrically coupled with the second contact electrode 32. The second contact electrode 32 can be coupled with an interconnection which commonly gives a predetermined potential to the n-GaN layers 22n of the μLEDs 220 (e.g., ground interconnection).

In the present embodiment, the electric circuit of the backplane 400 includes a plurality of metal layers which are respectively coupled with the first contact electrode 31 and the second contact electrode 32 (metal layers which function as the drain electrode 41 and the source electrode 42). In the present embodiment, the plurality of first contact electrodes 31 respectively cover the p-GaN layers 21p of the plurality of μLEDs 220 and function as a light-blocking layer or a light-reflecting layer. Each of the first contact electrodes 31 does not need to cover the upper surface of the μLED 220, i.e., the entirety of the upper surface of the p-GaN layer 21p. The shape, size and position of the first contact electrodes 31 are determined such that sufficiently-low contact resistance is realized while the first contact electrodes 31 sufficiently suppress arrival of light radiated from the emission layer 23 at the channel region of the TFT 40. Prevention of arrival of light radiated from the emission layer 23 at the channel region of the TFT 40 can also be realized by arranging the other metal layers at appropriate positions.

According to an embodiment of the present disclosure, the middle layer 300 that has a planarized upper surface is formed on the frontplane 200 that has a flat upper surface which is realized by filling the device isolation region 240 with the metal plugs 24 and the embedded insulator 25. These structures (underlying structures) function as a base on which circuit components such as TFTs are to be formed. In depositing semiconductors for TFT or in performing a heat treatment after the deposition, the above-described underlying structures are treated at, for example, 350° C. or higher. Thus, the embedded insulator 25 in the device isolation region 240 and the interlayer insulating layer 38 included in the middle layer 300 are preferably made of a material which will not be degraded even by a heat treatment at 350° C. or higher. For example, polyimide and SOG (Spin-on Glass) can be suitably used.

Then, before the crystal growth substrate 100 is removed, the step of dividing the multilayer structure on the crystal growth substrate 100 into a plurality of light-emitting device units 10 is performed. The embodiments of the present disclosure are not limited to this example. The step of dividing into a plurality of light-emitting device units 10 may be performed after these multilayer structures are delaminated from the crystal growth substrate 100,

In the present embodiment, the structure is cut at the positions indicated by broken lines of FIG. 7H with a laser beam or dicing blade. The broken lines represent the boundary of adjoining light-emitting device units 10. Along the broken lines, cut grooves are formed. The dicing step for cutting and isolation is desirably performed with an unshown dicing tape kept adhered to the lower surface 100B of the crystal growth substrate 100. This is because, in the case where the crystal growth substrate 100 is intentionally or unintentionally cut, respective ones of the light-emitting device units 10 can be maintained at predetermined positions.

Then, as shown in FIG. 7I, after cut grooves 10C are formed so as to reach the crystal growth substrate 100, the backplane 400 is covered with an expandable film 510, and the expandable film 510 and the backplane 400 are firmly attached together. The cut grooves 10C may partially cut the surface of the crystal growth substrate 100. From the viewpoint of reusing the crystal growth substrate 100, it is desirable that the lower end of the cut grooves 10C is coincident with the surface of the crystal growth substrate 100. One of the surfaces of the expandable film 510 which faces the backplane 400 is provided with an electrode pad and interconnection for electrically coupling with the backplane 400. The interconnection may have a material and configuration such that the interconnection can be expanded together with the expandable film 510. An example of such a material is a resin in which electrically-conductive particles are dispersed or an electrically-conductive polymer which itself has electrical conductivity. An example of such a configuration is a meandering or bent interconnection pattern. The interconnection has such a shape that, even when the expandable film 510 is expanded, no interconnection breakage occurs.

Then, the interface between the crystal growth substrate 100 and the frontplane 200 is irradiated with laser light 700 transmitted through the crystal growth substrate 100. For example, the laser light 700 at the wavelength of 248 nm enters the crystal growth substrate 100 from the lower surface 100B and is transmitted through the crystal growth substrate 100. In this case, the laser light 700 enters the frontplane 200 from the upper surface 100T of the crystal growth substrate 100 and is absorbed by a portion near the interface between the crystal growth substrate 100 and the frontplane 200 so that delamination occurs. Specifically, light at the wavelength of 248 nm is transmitted through a sapphire substrate but absorbed by GaN in a region at the depth of about 20 nm from the interface (surface). When the irradiation energy of such laser light 700 is, for example, about 800 mJ/cm², GaN which has absorbed the laser light 700 locally increases to about 1000° C. and decomposes into Ga atoms and N atoms. When the trench in the device isolation region 240 of the frontplane 200 reaches the upper surface 100T of the crystal growth substrate 100, part of the metal plug 24 and the embedded insulator 25 located at the interface between the device isolation region 240 and the crystal growth substrate 100 absorbs the laser light 700 and melts or decomposes (disappears). Laser light at the wavelength of 248 nm is generated by a KrF excimer laser light source and therefore can be suitably used for lift-off. As previously described, in the present embodiment, a sapphire substrate is suitably used.

In an embodiment of the present disclosure, the interface between the crystal growth substrate 100 and the frontplane 200 is irradiated with the laser light 700 in the shape of a line extending in a direction vertical to the drawing sheet of FIG. 7I (Y-axis direction), and the irradiation position is moved in X-axis direction. Part of the frontplane 200 or the buffer layer such as TiN layer which is in contact with the crystal growth substrate 100 absorbs the laser light 700 and decomposes (disappears). By scanning the above-described interface with the laser light 700, the frontplane 200 can be delaminated from the crystal growth substrate 100. The wavelength of the laser light 700 is typically in the ultraviolet band as described above. The wavelength of the laser light 700 is selected such that the laser light 700 is hardly absorbed by the crystal growth substrate 100 but is absorbed by the frontplane 200 or the buffer layer as much as possible.

The position of irradiation with the laser light 700 moves relative to the crystal growth substrate 100 for scanning with the laser light 700. In the laser lift-off apparatus, the crystal growth substrate 100 may be movable while the light source from which the laser light 700 is to be emitted and an optical unit are stationary, and vice versa.

Thereafter, as shown in FIG. 7J, the crystal growth substrate 100 is removed from the μLED device 1000 in the middle of the production process.

Then, the expandable film 510 is expanded in directions parallel to the XY plane, whereby the distance between the centers of the plurality of light-emitting device units 10 is increased. The distance between the centers before the expansion can be increased, for example, 1.2-2.5 times or more (about 5 times) by the expansion. As shown in FIG. 7L, after the expandable film 510 is expanded, a support member 520 is secured to the expandable film 510, whereby the configuration of FIG. 1A can be realized.

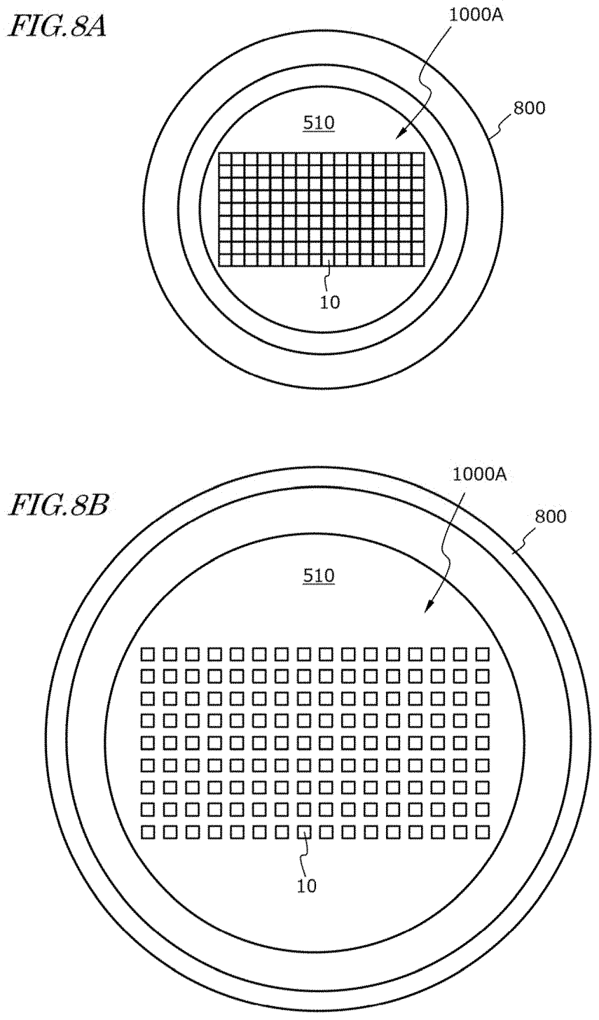

In expanding the expandable film 510 such that the structure transforms from the state of FIG. 7K to the state of FIG. 7L, for example, an expander 800 shown in FIG. 8A can be used. The expander 800 has such a configuration that the expander 800 is capable of holding a circumferential part of a circular expandable film 510 and expanding the expandable film 510 radially outward in the presence of applied heat. FIG. 8B shows a state where the expander 800 has expanded the expandable film 510 radially outward. According to the enlargement/expansion of the expandable film 510, the plurality of light-emitting device units 10 supported on the expandable film 510 are respectively positionally shifted such that the gap between the light-emitting device units 10 is enlarged. For example, after in this state the support member 520 is firmly attached to the expandable film 510 as shown in FIG. 7L, the expandable film 520 may be displaced from the expander 800.

Thereafter, the delaminated surface of the frontplane 200 is covered with the protecting film 540 shown in FIG. 1A. Before the delaminated surface of the frontplane 200 is covered with the protecting film 540, an insulating layer may be formed at the side surface of the light-emitting device units 10 or the space 530 may be filled with an insulator.

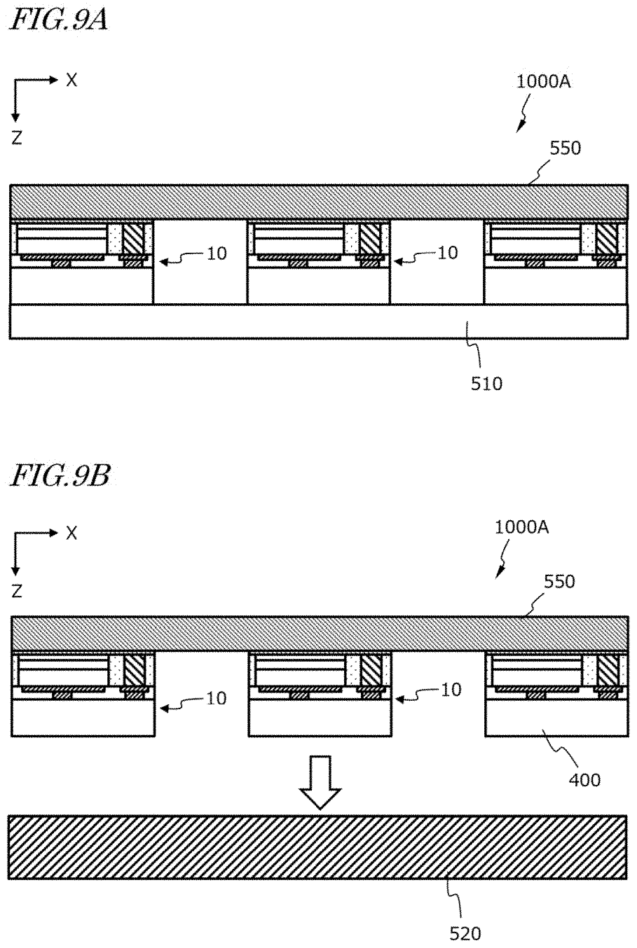

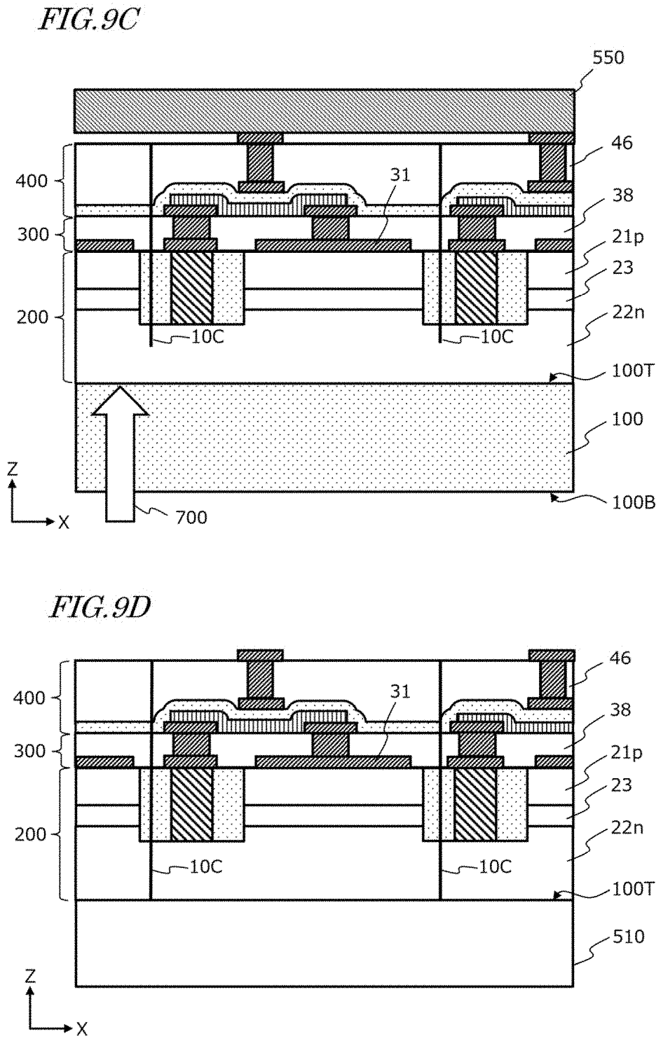

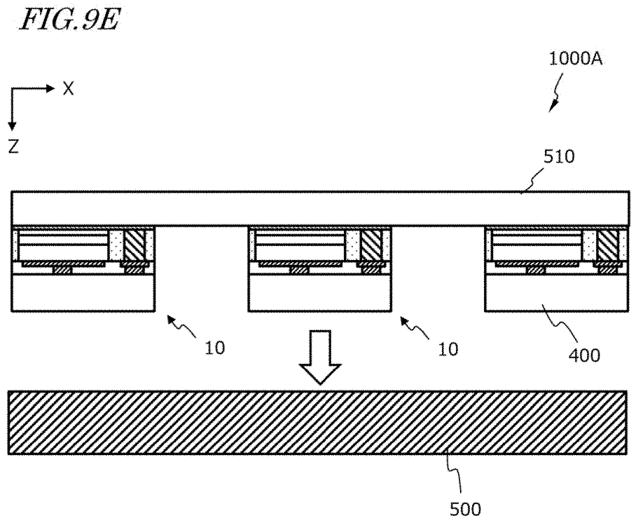

In the above-described example, the expandable film 510 functions as a constituent of a final μLED device 1000B, although the embodiments of the present disclosure are not limited to such an example. For example, after the expandable film 510 is expanded in directions parallel to the XY plane as previously described with reference to FIG. 7K such that the distance between the centers of the plurality of light-emitting device units 10 is increased, all of the light-emitting device units 10 may be fixed by a holding member 550 as shown in FIG. 9A. Between the holding member 550 and the light-emitting device units 10, for example, a sticky layer (not shown) is provided. Thereafter, the expandable film 510 is delaminated by, for example, UV irradiation. When the expandable film 510 functions as a constituent of a final μLED device 1000, the adhesive layer provided in the expandable film 510 is preferably made of an adhesive agent whose adhesive force would not be decreased by UV irradiation. When the expandable film 510 is finally delaminated as in the present embodiment, it is preferred that the adhesive force of the adhesive layer provided in the expandable film 510 decreases or disappears due to the UV irradiation.

Then, as shown in FIG. 9B, the light-emitting device units 10 which have been secured to the holding member 550 are secured to the supporting substrate 520. The holding member 550 may be realized by a film which functions as the previously-described protecting film 540, or the protecting film 540 may be adhered onto the holding member 550. Alternatively, after the holding member 550 is delaminated, the protecting film 540 may be adhered so as to cover all of the light-emitting device units 10. Instead of the protecting film 540, or together with the protecting film 540, a function layer such as a film including a touch sensor and/or a printed circuit board may be adhered.

In the above-described example, dividing grooves for division into the light-emitting device units 10 reach the crystal growth substrate 100 from the backplane 400 side, although the embodiments of the present disclosure are not limited to such an example. In the example of FIG. 7I, after the division is completed, the expandable film 510 is adhered to the backplane 400, although the embodiments of the present disclosure are not limited to such an example. As shown in FIG. 9C, after dividing grooves are formed so as not to reach the crystal growth substrate 100, the crystal growth substrate 100 may be delaminated. In this case, when necessary, the holding member 550 or the expandable film 510 may be adhered to the backplane 400. After the crystal growth substrate 100 is delaminated, the breaking step is performed to split the resultant structure at the dividing grooves, whereby division into respective light-emitting device units 10 is completed. The breaking step can be realized by, for example, pushing a linear or lattice-shaped rigid piece against lines at which the structure is to be split.

When the cutting is performed from the backplane 400 side, the cutting does not need to advance to the crystal growth substrate 100 and, therefore, shortening of the cutting time and reduction of wear of the blade are realized. In a form where the cut grooves 10C do not reach the crystal growth substrate 100, the crystal growth substrate 100 is delaminated without being impaired and is therefore reusable.

When the holding member 550 is adhered to the backplane 400 as shown in FIG. 9C, the expandable film 510 may be adhered to the frontplane 200 from which the crystal growth substrate 100 has been delaminated. FIG. 9D shows a state where the expandable film 510 has been adhered to the frontplane 200 and the holding member 550 has been delaminated away. Thereafter, the expandable film 510 is expanded, whereby the distance between the centers of the plurality of light-emitting device units 10 is increased. Thereafter, as shown in FIG. 9E, the backplane 400 of the plurality of light-emitting device units 10 is firmly attached to the supporting substrate 500. Thereafter, the expandable film 510 is delaminated away, and the light-emitting device units 10 can be covered with a protecting film or the like.

The mode of increasing the distance between the centers of the light-emitting device units 10 using the expandable film 510 can have many variations.

The configuration of TFTs included in the electric circuit in the backplane 400 is not limited to the above-described examples.

In an embodiment of the present disclosure, in the initial phase of the process of forming the TFT 40, a plurality of metal layers are formed so as to be in contact with the first and second contact electrodes 31, 32 of the frontplane 200 via the contact holes 39 of the interlayer insulating layer 38 in the middle layer 300. These metal layers can be the drain electrode 41 or the source electrode 42 of the TFT 40 but are not limited to such examples.

In the present embodiment, the drain electrode 41 and the source electrode 42 are formed by depositing a metal layer on the interlayer insulating layer 38 in the planarized middle layer 300 and thereafter patterning the metal layer by photolithography and etching. Therefore, misalignment which can cause decrease in yield will not occur between the frontplane 200 (the middle layer 300) and the backplane 400.

<TiN Buffer Layer>

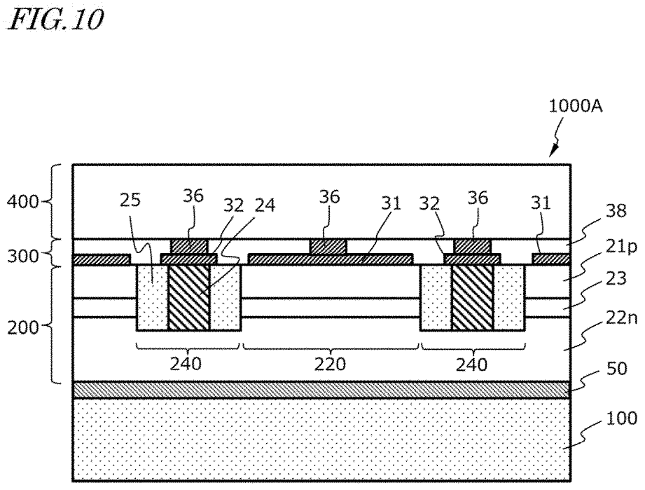

FIG. 10 is a cross-sectional view schematically showing part of a μLED device which includes a titanium nitride (TiN) layer 50 located between the crystal growth substrate 100 and the n-GaN layer 22n of each of the μLEDs 220. The thickness of the TiN layer 50 can be, for example, not more than 5 nm and not less than 20 nm. The TiN layer 50 can be suitably used in combination with a crystal growth substrate 100 which is made of sapphire, monocrystalline silicon or SiC, although the crystal growth substrate 100 is not limited to these substrates.

The TiN layer 50 is electrically conductive. Although there is a probability that the TiN layer 50 will be impaired in delaminating the crystal growth substrate 100, the TiN layer 50 provides particularly useful effects when the crystal growth substrate 100 is divided for respective ones of the light-emitting device units 10 and used while it is firmly attached to the light-emitting device units 10. In an embodiment where a plurality of μLEDs 220 are arrayed in each of the light-emitting device units 10 and at least one metal plug 24 couples the n-GaN layer 22n of the μLEDs 220 with the electric circuit of the backplane 400, if an electrical resistance component (sheet resistance) relative to the electric current flowing from the n-GaN layer 22n to the metal plug 24 is excessively high, an increase in power consumption will be caused. The TiN layer 50 functions as a buffer layer which relaxes the lattice mismatch in crystal growth and contributes to reduction in density of crystallographic defects, and also contributes to reduction in the above-described electrical resistance component in the operation of the device. The thickness of the TiN layer 50 is preferably not less than 10 nm, more preferably not less than 12 nm, from the viewpoint of reducing the electrical resistance component such that it can function as the substrate-side electrode. Meanwhile, from the viewpoint of transmitting light radiated from the μLEDs 220, the thickness of the TiN layer 50 is preferably, for example, not more than 20 nm.

FIG. 10 is a cross-sectional view schematically showing part of an embodiment where a plurality of μLEDs 220 are included in each of the light-emitting device units 10 and the divisional pieces of the crystal growth substrate 100 are constituents of a final μLED device 1000A. In the example shown in FIG. 10, a single continuous n-GaN layer 22n (second semiconductor layer) is shared among the plurality of μLEDs 220. However, the n-GaN layer 22n may be isolated for each of the μLEDs 220. In that case, the bottom of a trench which defines the device isolation region 240 reaches the upper surface of the TiN layer 50, and the metal plugs 24 are in contact with the TiN layer 50. Since the single continuous TiN layer 50 is electrically coupled with the n-GaN layer 22n in all of the μLEDs 220, electrical conduction between the metal plug 24 and the n-GaN layer 22n of each of the μLEDs 220 is secured. In this example, the TiN layer 50 functions as the n-side common electrode of the plurality of μLEDs 220. In an embodiment of the present disclosure, the electrodes on the second conductivity side in the plurality of μLEDs 220 are realized in a common form by a semiconductor layer or a TiN layer. Thus, a problem of conduction failure in some of the μLEDs 220 due to interconnection breakage is avoided.

<Other Configuration Examples of Metal Plug>

Hereinafter, other configuration examples of the embodiment are described where a plurality of μLEDs 220 are included in each of the light-emitting device units 10 and the divisional pieces of the crystal growth substrate 100 are constituents of a final μLED device 1000A.

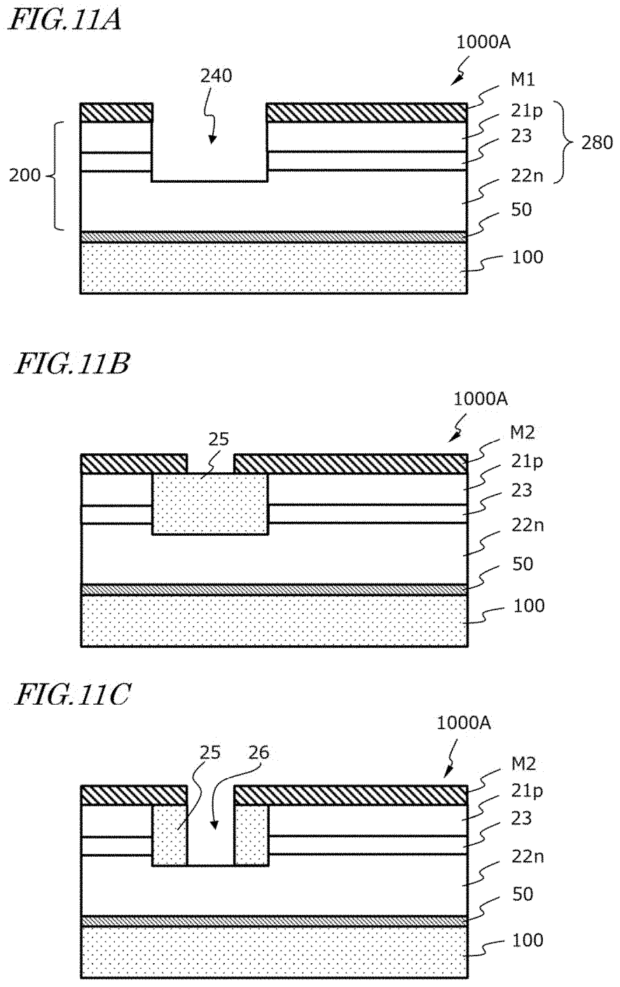

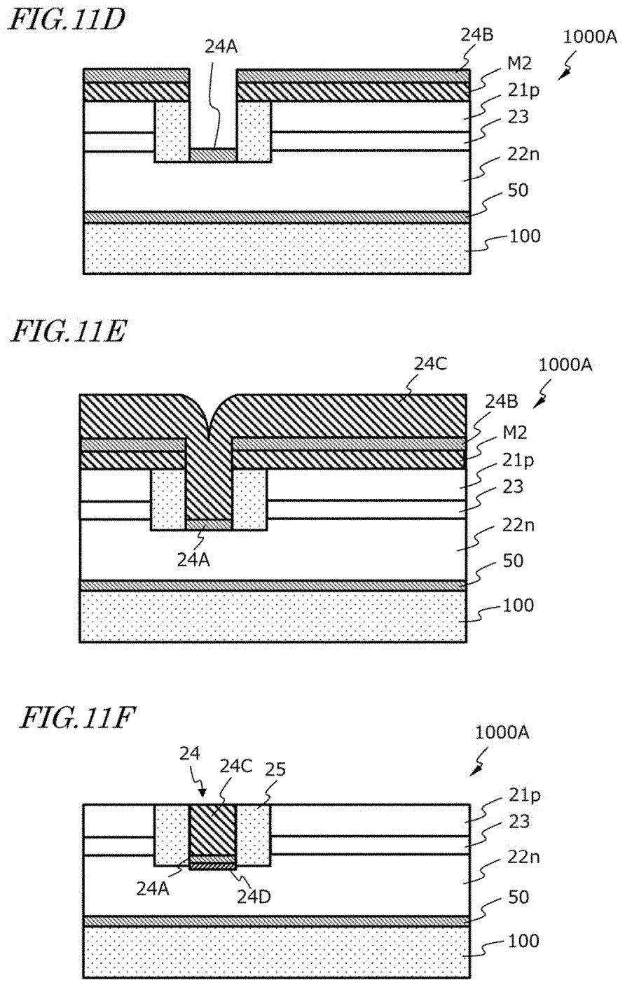

An example of the configuration and formation method of a μLED device is described with reference to FIG. 11A through FIG. 11F where the metal plug includes a titanium nitride layer which is in contact with the second semiconductor layer. Formation of the semiconductor multilayer structure 280 can be carried out according to the previously-described method.

First, as shown in FIG. 11A, a mask M1 is formed so as to have an opening which defines the shape, position and size of the device isolation region 240 and, thereafter, a trench is formed in a region where the device isolation region 240 is to be formed. This etching can be carried out by, for example, inductively coupled plasma (ICP) etching. Specifically, the etching can be carried out using a plasma of a chloric gas, such as Cl₂, BCl₃, SiCl₄, or CHCl₃, or, a mixture gas prepared by diluting a chloric gas with a rare gas or the like. The depth of the etching is determined such that the n-GaN layer 22n appears at the bottom of the trench. The trench is filled with the embedded insulator 25. Specifically, the embedded insulator 25 can be formed by, for example, applying a resin material such as thermosetting polyimide and thereafter curing the resin material by a heat treatment at, for example, 400° C. for 60 minutes. The embedded insulator 25 does not need to be made of a resin but may be made of an inorganic insulative material such as, for example, silicon nitride, silicon oxide, or the like.

In an embodiment of the present disclosure, TFTs and other constituents included in the backplane 400 are formed in a layer lying above the frontplane 200 and the middle layer 300 by a semiconductor manufacture technique, and therefore, the frontplane 200 and the middle layer 30 need to be made of materials which are resistant to the process temperature for formation of these constituents. For example, the embedded insulator 25, the interlayer insulating layer 38 and the insulating layer 46 can be made of an organic material, but the organic material needs to be resistant to the highest temperature in the process of forming the backplane 400. Specifically, if the step of forming TFTs includes a heat treatment at a temperature higher than 300° C., for example, the embedded insulator 25, the interlayer insulating layer 38 and/or the insulating layer 46 can be made of a heat-resistant resin material which is unlikely to degrade even in a heat treatment at 300° C. (e.g., polyimide).

Each of the embedded insulator 25, the interlayer insulating layer 38 and the insulating layer 46 does not need to have a single-layer structure but may have a multilayer structure. The multilayer structure can include, for example, a stack of an organic material and an inorganic material.

Then, as shown in FIG. 11B, a mask M2 is formed so as to have an opening which defines the shape, position and size of the through hole 26 that is to be formed in the embedded insulator 25. The mask M2 can be a resist mask. After the thus-configured mask M2 is formed, for example, anisotropic etching with an electron cyclotron resonance (ECR) plasma is performed, whereby the through hole 26 can be formed in the embedded insulator 25 as shown in FIG. 11C. When the embedded insulator 25 is made of polyimide, the etching can be carried out using a plasma of an oxygen gas or a plasma of an oxygen gas with CF₄ added thereto. When the embedded insulator 25 is made of silicon nitride or silicon oxide, the etching can be carried out using a plasma of, for example, a CF₄ or CHF₃ gas.

In the present embodiment, as shown in FIG. 11D, Ti is deposited by sputtering or the like without immediately removing the mask M2 that is formed by a resist, whereby a Ti layer 24A (thickness: 10-150 nm, typically about 30 nm) is formed at the bottom of the through hole 26. On the mask M2, a Ti layer 24B is also formed.

Then, as shown in FIG. 11E, an Al deposit 24C (thickness: 500-2000 nm) is formed by sputtering or the like. The thickness of the Al deposit 24C is determined such that the Al deposit 24C fills the inside of the through hole 26. The Al deposit 24C is also formed on the mask M2. Thereafter, unnecessary parts of the Ti layer 24B and the Al deposit 24C are removed together with the mask M2 (lift-off process). After the mask M2 is removed, when necessary, polishing is performed for planarization such that the upper surface of the device isolation region 240 is coplanar with the upper surface of the μLEDs 220. The planarization by polishing may be performed without performing the lift-off process.

After the mask M2 is removed, short annealing is performed at, for example, 600° C. for 30 seconds. If planarization is performed, it does not matter whether the short annealing is performed before or after the planarization. As shown in FIG. 11F, this annealing causes at least part of the Ti layer 24A to react with the n-GaN layer 22n and, as a result, a TiN layer 24D (thickness: 5-50 nm) is formed. The TiN layer 24D contributes to realization of a low-resistance ohmic contact with the n-GaN layer 22n.

In the example shown in FIG. 11F, the TiN layer 50 is located on the upper surface of the crystal growth substrate 100, although the TiN layer 50 is not indispensable. On the upper surface of the crystal growth substrate 100, another buffer layer may be provided.

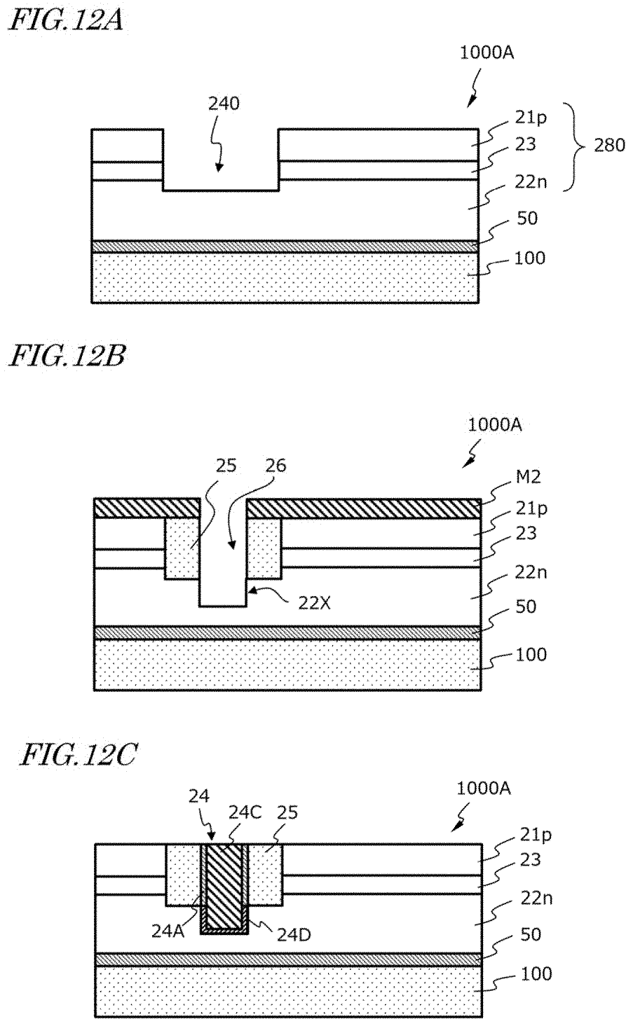

Next, an example of the configuration and formation method of a μLED device is described with reference to FIG. 12A through FIG. 12C where the metal plug 24 extends beyond the embedded insulator 25 so as to be in contact with the recessed portion of the n-GaN layer 22n.

First, as shown in FIG. 12A, a trench is formed in a region where the device isolation region 240 is to be formed.

As shown in FIG. 12B, after the embedded insulator 25 is formed, a mask M2 is formed so as to have an opening which defines the shape, position and size of the through hole 26 that is to be formed in the embedded insulator 25. After the embedded insulator 25 is etched using the mask M2, subsequently, the n-GaN layer 22n is etched to form a recessed portion 22X. In this way, the through hole 26 is formed whose bottom is deeper than the bottom of the embedded insulator 25. The level difference between the bottom of the embedded insulator 25 and the bottom of the through hole 26 is, for example, not less than 200 nm and not more than 1000 nm. The etching of the embedded insulator 25 and the etching of the n-GaN layer 22n can be carried out using different etching apparatuses and/or different etching gases which are suitable to respective ones of them.

As shown in FIG. 12C, a Ti layer 24A (thickness: 10-150 nm) is formed on the inner wall surface and the bottom surface of the through hole 26. By using a sputtering method which is excellent in step coverage, the Ti layer 24A can be formed not only on the bottom surface of the through hole 26 but also on the inner wall surface, particularly on the inner wall surface of the recessed portion 22X of the n-GaN layer 22n. Thereafter, by the previously-described method, the inside of the through hole 26 is filled with an Al deposit 24C. Before or after formation of the Al deposit 24C, short annealing is performed at, for example, 600° C. for 30 seconds. This annealing causes at least part of the Ti layer 24A to react with the n-GaN layer 22n and, as a result, a TiN layer 24D (thickness: 5-50 nm) is formed. The TiN layer 24D is also formed on the side surface of the recessed portion 22X of the n-GaN layer 22n and, therefore, the contact area between the TiN layer 24D and the n-GaN layer 22n increases. Thus, the TiN layer 24D that has a larger contact area contributes to further reduction in resistance of the ohmic contact with the n-GaN layer 22n.

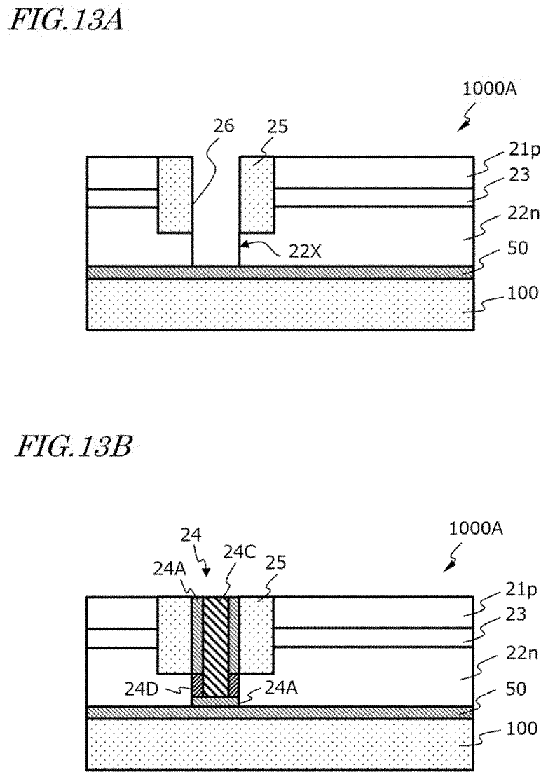

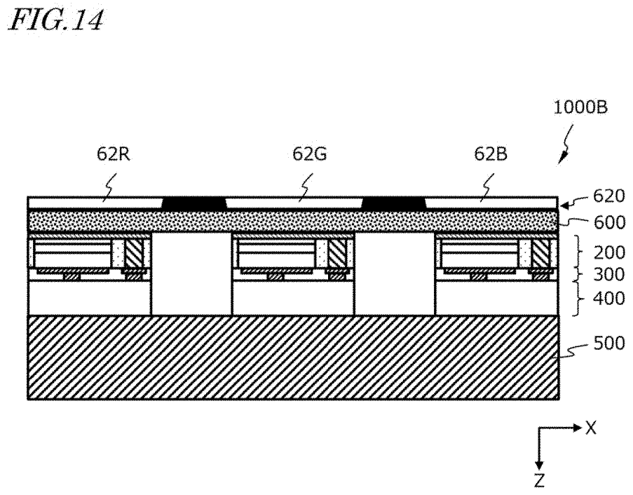

Next, an example of the configuration and formation method of a μLED device is described with reference to FIG. 13A and FIG. 13B where the metal plug 24 extends beyond the embedded insulator 25 and includes a Ti layer 24A which is in contact with the TiN layer 50.

By the same method as that described above, a through hole 26 is formed as shown in FIG. 13A. The difference of the configuration shown in FIG. 13A from the previously-described configurations resides in that the bottom of the recessed portion 22X formed in the n-GaN layer 22n reaches the TiN layer 50. In other words, the through hole 26 penetrates through the semiconductor layers and reaches the TiN layer 50. The through hole 26 is preferably formed such that the TiN layer 50 is exposed at the bottom of the through hole 26, although the through hole 26 may penetrate through the TiN layer 50 and reach the crystal growth substrate 100.

Then, as shown in FIG. 13B, a Ti layer 24A is formed on the inner wall surface and the bottom surface of the through hole 26. Thereafter, by the previously-described method, the inside of the through hole 26 is filled with an Al deposit 24C. Before or after formation of the Al deposit 24C, short annealing is performed at, for example, 600° C. for 30 seconds. This annealing causes at least part of the Ti layer 24A to react with the n-GaN layer 22n and, as a result, a TiN layer 24D (thickness: 5-50 nm) is formed. The TiN layer 24D is formed on the side surface of the recessed portion 22X of the n-GaN layer 22n. At the bottom of the through hole 26, the Ti layer 24A is in contact with the TiN layer 50.

In a variation of this example, the annealing for changing part of the Ti layer 24A into the TiN layer 24D may be omitted. This is because, at the bottom of the through hole 26, a low-resistance ohmic contact is realized between the Ti layer 24A and the TiN layer 50.

In the example shown in FIG. 13B, the TiN layer 50 is necessary between the crystal growth substrate 100 and the n-GaN layer 22n of each of the μLEDs 220, while in the example shown in FIG. 11F and FIG. 12C, the TiN layer 50 is not indispensable.

In the above-described examples, the upper surface of the metal plug 24 is present on generally the same plane as the upper surface of each of the μLEDs 220 and, therefore, it is possible to form circuit components such as TFTs 40 and fine interconnections on the upper surface with high precision by a semiconductor manufacture technique.

Hereinafter, a color display embodiment realized by the μLED device of the present disclosure is described.

<Color Display I>

Hereinafter, a configuration example of a μLED device 1000B of an embodiment of the present disclosure which is capable of full-color displaying is described with reference to FIG. 14. Components corresponding to the components of the previously-described μLED device 1000 are designated by the same reference numbers, and the descriptions of those components are not repeated in this section.

The μLED device 1000B of the present embodiment includes a frontplane 200, a middle layer 300, a backplane 400, and a supporting substrate 500. These components can include various constituents described in the foregoing sections.

The μLED device 1000B shown in FIG. 14 further includes a phosphor layer 600 which is capable of converting light radiated from each of the plurality of μLEDs 220 to white light and a color filter array 620 which is capable of selectively transmitting respective color components of the white light. The color filter array 620 is supported by the frontplane 200 with the phosphor layer 600 interposed therebetween. The color filter array 620 includes a red filter 62R, a green filter 62G, and a blue filter 62B. In the example shown in the drawing, the TiN layer 50 is provided as the conductor layer on the frontplane 200. In the frontplane 200, the μLEDs are isolated pieces. Thus, when the supporting substrate 500 is a flexible substrate, the μLED device 1000B functions as a flexible display. The same also applies to color displays which will be described later.

In the present embodiment, the composition and bandgap of the emission layer 23 are adjusted such that light radiated from the emission layer 23 of the μLEDs 220 has a wavelength of blue (435-485 nm).

An example of the phosphor layer 600 can be a sheet which contains a large number of nanoparticles called “quantum dots” (quantum dot phosphor). The quantum dot phosphor can be made of a semiconductor such as, for example, CdTe, InP, GaN, or the like. The wavelength of light emitted from the quantum dot phosphor changes depending on the size of the quantum dot phosphor. A quantum dot dispersed sheet which is configured to receive excitation light and emit red light and green light can be used as the phosphor layer 600. When blue light is used as light for exciting the thus-configured phosphor layer 600, white light resulting from mixture of blue light transmitted through the phosphor layer 600 and red or green light produced by conversion by the quantum dots of the phosphor layer 600 can be emitted from the phosphor layer 600.

The particle diameter of the quantum dot phosphor is, for example, not less than 2 nm and not more than 30 nm. As compared with usual phosphor powder particles whose particle diameter is greater than 10 μm, the particle diameter of the quantum dot phosphor is fairly small. When the μLEDs 220 are arrayed at a narrow pitch of, for example, about 5-10 μm, efficient wavelength conversion is difficult with phosphor powder particles whose particle diameter is greater than 10 μm. It is known that, if usual phosphor powder particles are crushed down so as to have a particle diameter smaller than 1 μm, the phosphor performance significantly deteriorates.

The phosphor layer 600 may include a scatterer which has such a size that the scatterer is capable of mainly Rayleigh scattering blue light (excitation light). Rayleigh scattering is caused by a particle which is smaller than the wavelength of the excitation light. As a scatterer for selectively scattering blue light, titanium oxide (TiO₂) ultrafine particles whose diameter is not less than 10 nm and not more than 50 nm (typically not more than 30 nm) can be suitably used. Particularly, TiO₂ ultrafine particles of rutile crystal are physically and chemically stable and hence preferred. Such TiO₂ ultrafine particles have a low effect of scattering light of colors (green and red) whose wavelength is longer than the wavelength of blue.

To uniformly disperse TiO₂ ultrafine particles across the phosphor layer 600, it is preferred to perform a surface treatment with the use of an organic substance, such as alkanolamine, polyol, siloxane, or carboxylic acid (e.g., stearic acid or lauric acid). Alternatively, a surface treatment with the use of an inorganic substance, such as Al(OH)₃ or SiO₂, may be performed.

As the blue scatterer, zinc oxide fine particles (particle diameter: for example, not less than 20 nm and not more than 100 nm) may be used instead of, or together with, titanium oxide fine particles. When such a blue scatterer is uniformly dispersed, color unevenness which depends on the direction is unlikely to occur, and displaying with excellent view angle characteristics is realized.

In the color filter array 620, the red filter 62R, the green filter 62G, and the blue filter 62B are located at positions which respectively face the μLEDs 220. The red filter 62R, the green filter 62G, and the blue filter 62B respectively receive white light from the phosphor layer 600 excited by light radiated from corresponding ones of the μLEDs 220 and transmit the red component, the green component, and the blue component contained in the white light.

From the viewpoint that light radiated from each of the μLEDs 220 is caused to efficiently arrive at any corresponding one of the red filter 62R, the green filter 62G, and the blue filter 62B, it is desirable that the metal plugs 24, 250 have such a shape that surrounds each of the PLED devices 1000B.

In the color filter array 620, it is preferred that between the red filter 62R, the green filter 62G, and the blue filter 62B there is a portion which is made of a light-blocking or light-absorbing material and which functions as the black matrix.

The phosphor layer 600 may be a phosphor sheet stacked on the color filter array 620.

The phosphor layer 600 does not need to be a sheet in which a quantum dot phosphor is dispersed. The phosphor layer 600 may be formed by applying a resin, in which a quantum dot phosphor (phosphor powder) is dispersed, onto the delaminated surface side of the frontplane 200 and curing the resin. In this case, the phosphor powder is located on the delaminated surface side of the frontplane 200.

The other elements than the phosphor layer 600 and the color filter array 620, such as an optical sheet, a protector sheet, a touch sensor, or the like, may be attached to the frontplane 200. The same applies to embodiments which will be described in the following sections.

<Color Display II>

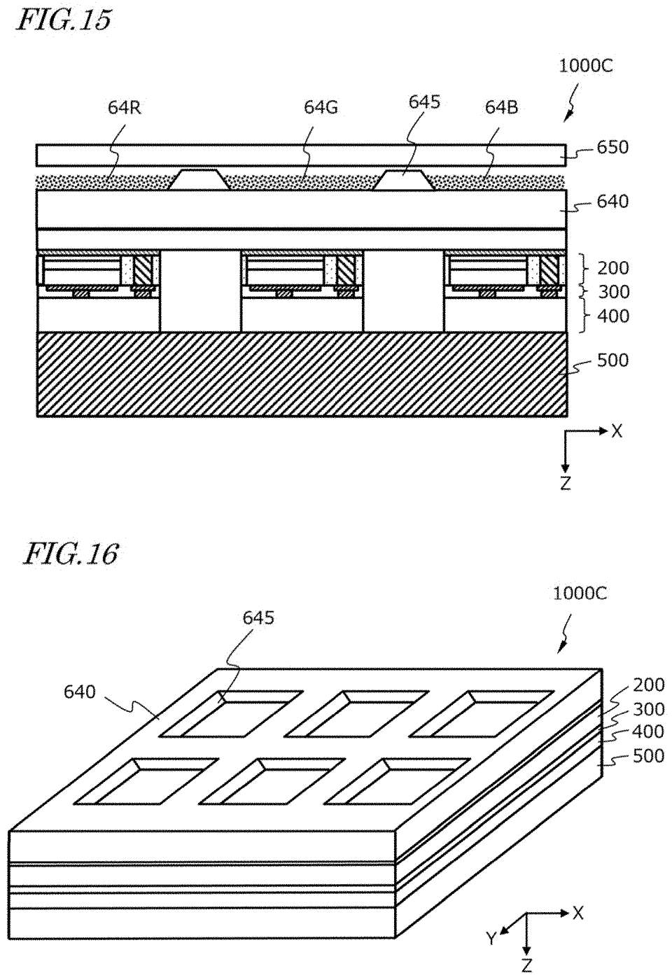

Hereinafter, a configuration example of a μLED device 1000C of an embodiment of the present disclosure which is capable of full-color displaying is described with reference to FIG. 15 and FIG. 16. FIG. 16 is a perspective view of the μLED device 1000C.

The μLED device 1000C of the present embodiment includes a frontplane 200, a middle layer 300, a backplane 400, and a supporting substrate 500. These components can include various constituents described in the foregoing sections.

The μLED device 1000C shown in the drawings includes a bank layer 640 (thickness: 0.5-3.0 μm) which is supported by the frontplane 200 and which defines a plurality of pixel openings 645 where light radiated from a plurality of μLEDs respectively arrives. The μLED device 1000C further includes a red phosphor 64R, a green phosphor 64G, and a blue scatterer 64B which are provided in respective ones of the plurality of pixel openings 645 of the bank layer 640. The red phosphor 64R converts blue light radiated from the μLED 220 to red light. The green phosphor 64G converts blue light radiated from the μLED 220 to green light. The blue scatterer 64B scatters blue light radiated from the μLED 220. The blue scatterer 64B can be designed so as to have a radiation angle dependence which is similar to the radiation angle dependence exhibited by the intensity of light emitted from the red phosphor 64R or the green phosphor 64G (e.g., Lambertian distribution).

In the present embodiment, the composition and bandgap of the emission layer 23 are adjusted such that light radiated from the emission layer 23 of the μLEDs 220 has a wavelength of blue (435-485 nm).

In the example shown in FIG. 15, the μLED device 1000C includes a transparent protecting layer 650 which covers the pixel openings 645 of the bank layer 640. For the sake of simplicity, the transparent protecting layer 650 is not shown in FIG. 16. If the red phosphor 64R and the green phosphor 64G are likely to degrade due to absorption of moisture, it is desirable that the transparent protecting layer 650 performs a sealing function such that moisture from the air does not cause adverse effects on these phosphors. The transparent protecting layer 650 may have a multilayer structure of an organic layer and an inorganic layer.

The bank layer 640 has, for example, a lattice shape and can be made of a light-blocking material in which a black dye is dissolved or a light-blocking material in which a black pigment such as carbon black is dispersed. The bank layer 640 can be made of a photosensitive material, a resin material such as acrylic resin, polyimide, or the like, a paste material including low melting point glass, or a sol-gel material (e.g., SOG). When the bank layer 640 is made of a photosensitive material, the pixel openings 645 may be formed at predetermined positions by applying the photosensitive material to the frontplane 200 and thereafter performing patterning by exposure and development in the lithography process. The position and size of the pixel openings 645 are determined so as to be in harmony with the arrangement of the μLEDs 220. The size of the pixel openings 645 can be, for example, not more than 10 μm×10 μm. The particle diameter of the red phosphor 64R, the green phosphor 64G, and the blue scatterer 64B is desirably not more than 1 μm. The red phosphor 64R and the green phosphor 64G can each be suitably made of a quantum dot phosphor. The blue scatterer 64B can be made of transparent powder particles whose particle diameter is not less than 10 nm and not more than 60 nm.

The blue scatterer 64B can be prepared by dispersing particles whose particle diameter is about 10% of the wavelength of blue light radiated from the μLEDs 220 (e.g., about 450 nm) in a matrix material whose refractive index is sufficiently lower than the refractive index (n) of the particles. The thus-formed blue scatterer 64B can cause Rayleigh scattering of blue light. The powder particles which are constituents of the blue scatterer 64B can be made of an inorganic oxide such as, for example, titanium oxide (n=2.5 to 2.7), chromium oxide (n=2.5), zirconium oxide (n=2.2), zinc oxide (n=1.95), or alumina (n=1.76). The refractive index of the matrix material is desirably lower than the refractive index of the powder particles by 0.25 or more, for example 0.5 or more.

The delaminated surface of the frontplane 200 may have an irregular surface which acts on light radiated from the μLEDs 220. The presence of such an irregular surface modulates the radiation intensity dependence of light radiated from the red phosphor 64R, the green phosphor 64G, and the blue scatterer 64B or the reflectance at the delaminated surface of the frontplane 200.

<Color Display III>

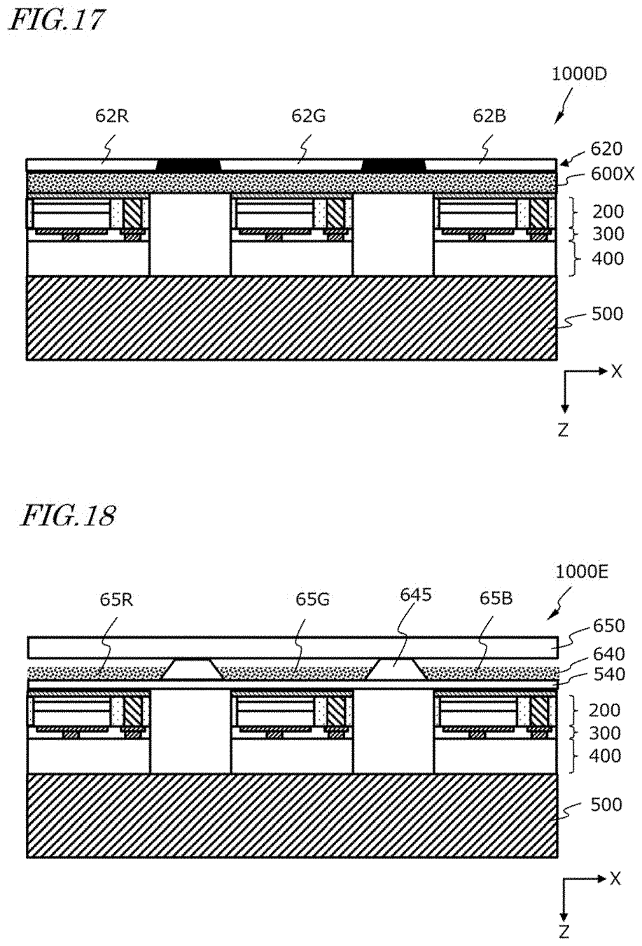

Hereinafter, a configuration example of a μLED device 1000D of an embodiment of the present disclosure which is capable of full-color displaying is described with reference to FIG. 17. Components corresponding to the components of the previously-described μLED device 1000A are designated by the same reference numbers, and the descriptions of those components are not repeated in this section.

The μLED device 1000D of the present embodiment includes a frontplane 200, a middle layer 300, a backplane 400, and a supporting substrate 500. These components can include various constituents described in the foregoing sections.

The μLED device 1000D shown in FIG. 17 further includes a phosphor layer 600X which is capable of converting light radiated from each of the plurality of μLEDs 220 to white light and a color filter array 620 which is capable of selectively transmitting respective color components of the white light. The color filter array 620 is supported by the frontplane 200 with the phosphor layer 600X interposed therebetween. The color filter array 620 includes a red filter 62R, a green filter 62G, and a blue filter 62B.

In the present embodiment, the composition and bandgap of the emission layer 23 are adjusted such that light radiated from the emission layer 23 of the μLEDs 220 has a wavelength of ultraviolet (e.g., 365-400 nm) or a wavelength of bluish violet (400 nm to 420 nm; typically 405 nm). Specifically, in In_{y}Ga_{1-y}N that forms the emission layer 23, the molar fraction of In, y, is set within the range of 0≤y≤0.15, for example. When y=0, emission of light at a wavelength of 365 nm is achieved. When y=0.1, emission of light at a wavelength of bluish violet is achieved. Note that when the semiconductor layer that forms the emission layer 23 is made of AlGaN or InAlGaN, light can be radiated at a wavelength shorter than 365 nm.

An example of the phosphor layer 600X can be a sheet which contains a large number of nanoparticles called “quantum dots” (quantum dot phosphor). The quantum dot phosphor can be made of a semiconductor such as, for example, CdTe, InP, GaN, or the like. The wavelength of light emitted from the quantum dot phosphor changes depending on the size of the quantum dot phosphor. A quantum dot dispersed sheet which is configured to receive excitation light and emit red light, green light, and blue light can be used as the phosphor layer 600X. When ultraviolet or bluish violet light is used as light for exciting the thus-configured phosphor layer 600X, white light resulting from mixture of red, green, or blue light produced by conversion from excitation light by the quantum dots of the phosphor layer 600X can be emitted from the phosphor layer 600X.

The phosphor of the quantum dots is dispersed in a matrix which is made of an organic resin, an inorganic material such as low melting point glass, or a hybrid material prepared from an organic material and an inorganic material. The amount (weight proportion) of the phosphor to be dispersed decreases in the order of blue, green, and red.

In one example, the quantum dot phosphor has a core-shell structure. The core can be made of, for example, CdS, InP, InGaP, InN, CdSe, GaInN, or ZnCdSe. Particularly for generating emission of light at a wavelength of 360 nm to 460 nm, a phosphor whose core is made of CdS can be suitably used. When the core is made of CdS, emission of blue at a wavelength of 440 nm to 460 nm can be generated by adjusting the particle diameter of the core in a range of 4.0 nm to 7.3 nm. When the core is made of any other material (InP, InGaP, InN, or CdSe), for example, the particle diameter of 1.4 nm to 3.3 nm enables generation of blue light (center wavelength 475 nm), the particle diameter of 1.7 nm to 4.2 nm enables generation of green light (center wavelength 530 nm), and the particle diameter of 2.0 nm to 6.1 nm enables generation of red light (center wavelength 630 nm). The type of the material of the quantum dot can be appropriately determined based on the quantum efficiency, the particle diameter, or etc. A quantum dot phosphor whose core is made of In_{0.5}Ga_{0.5}P has a relatively large particle diameter and is therefore, advantageously, easy in production. To achieve a higher quantum efficiency, it is desirable that the core of the quantum dot used is made of, for example, InP that does not contain Ga.

The differences of the μLED device 1000D of the present embodiment from the previously-described μLED device 1000B reside in the wavelength of light radiated from the μLEDs 220 (excitation light) and the configuration of the phosphors. In the other points, the μLED device 1000D may have the same configuration as the μLED device 1000B.

Instead of using light as radiated from the μLEDs 220 as one of the primary colors, in the present embodiment, light radiated from the μLEDs 220 is used for exciting respective ones of red, green, and blue phosphors. Therefore, even if the emission wavelength of the μLEDs 220 varies or shifts, color unevenness is unlikely to occur. The emission wavelength of the μLEDs 220 can vary depending on the composition of the emission layer 23, the magnitude of the driving current, the temperature, or etc. However, in the present embodiment, quantum dot phosphors are used for respective ones of the primary colors, and therefore, even if the wavelength of the excitation light varies due to the above-described causes, it hardly affects the wavelength of light outgoing from the phosphors. Thus, according to the present embodiment, color unevenness is unlikely to occur, and more excellent display characteristics are realized.

<Color Display IV>

Hereinafter, a configuration example of a μLED device 1000E of an embodiment of the present disclosure which is capable of full-color displaying is described with reference to FIG. 18.

The μLED device 1000E of the present embodiment includes a frontplane 200, a middle layer 300, a backplane 400, and a supporting substrate 500. These components can include various constituents described in the foregoing sections. In the present embodiment, likewise as in the example of FIG. 17, the composition and bandgap of the emission layer 23 are adjusted such that light radiated from the emission layer 23 of the μLEDs 220 has a wavelength of ultraviolet (e.g., 365-400 nm) or a wavelength of bluish violet (e.g., 400-420 nm; typically 405 nm).

The μLED device 1000E shown in the drawing includes a bank layer 640 (thickness: 0.5-3.0 μm) which is supported by the protecting film 540 on the frontplane 200 and which defines a plurality of pixel openings 645 where excitation light radiated from a plurality of μLEDs respectively arrives. The μLED device 1000E further includes a red quantum dot phosphor 65R, a green quantum dot phosphor 65G, and a blue quantum dot phosphor 65B which are provided in respective ones of the plurality of pixel openings 645 of the bank layer 640. The red phosphor 65R converts excitation light radiated from the μLED 220 to red light. The green phosphor 65G converts excitation light radiated from the μLED 220 to green light. The blue phosphor 65B converts excitation light radiated from the μLED 220 to blue light.

The quantum dot phosphors 65R, 65G, 65B of respective colors can be made of the materials previously described in conjunction with the phosphor layer 600X of the color display IV. In the present embodiment, the quantum dot phosphors 65R, 65G, 65B of different colors are located in spatially-separated regions, although in the phosphor layer 600X quantum dot phosphors for converting excitation light to red, green, and blue light are mixedly provided.

The differences of the μLED device 1000E of the present embodiment from the previously-described μLED device 1000D reside in the wavelength of light radiated from the μLEDs 220 (excitation light) and the configuration of the phosphors. In the other points, the μLED device 1000E may have the same configuration as the μLED device 1000D.

Instead of using light as radiated from the μLEDs 220 as one of the primary colors, in the present embodiment, light radiated from the μLEDs 220 is used for exciting respective ones of red, green, and blue phosphors. Therefore, as previously described, even if the emission wavelength of the μLEDs 220 varies or shifts, color unevenness is unlikely to occur, and more excellent display characteristics are realized.

### INDUSTRIAL APPLICABILITY

An embodiment of the present invention provides a novel micro-LED device. When the micro-LED device is used as a display, the micro-LED device is broadly applicable to smartphones, tablet computers, on-board displays, and, small-, medium-, and large-sized television sets. The uses of the micro-LED device are not limited to displays.

### REFERENCE SIGNS LIST

21 . . . First semiconductor layer, 22 . . . Second semiconductor layer, 23 . . . Emission layer, 24 . . . Metal plug, 25 . . . Embedded insulator, 31 . . . First contact electrode, 32 . . . Second contact electrode, 36 . . . Via electrode, 38 . . . Interlayer insulating layer, 100 . . . Crystal growth substrate, 200 . . . Frontplane, 220 . . . μLED, 240 . . . Device isolation region, 300 . . . Middle layer, 400 . . . Backplane, 1000 . . . μLED device

1. A micro-LED device comprising:
a supporting substrate;
a frontplane including a plurality of micro-LEDs, each of which includes a first semiconductor layer of a first conductivity type and a second semiconductor layer of a second conductivity type, and a device isolation region located between the plurality of micro-LEDs, the device isolation region including at least one metal plug electrically coupled with the second semiconductor layer;
a middle layer supported by the frontplane, the middle layer including a plurality of first contact electrodes respectively electrically coupled with the first semiconductor layer of the plurality of micro-LEDs and at least one second contact electrode coupled with the metal plug; and
a backplane supported by the middle layer, the backplane including an electric circuit electrically coupled with the plurality of micro-LEDs via the plurality of first contact electrodes and the at least one second contact electrode, the electric circuit including a plurality of thin film transistors,
wherein the frontplane, the middle layer and the backplane are divided into a plurality of light-emitting device units which are two-dimensionally arrayed, the plurality of light-emitting device units being supported by the supporting substrate, and
each of the plurality of thin film transistors includes a semiconductor layer deposited on the frontplane and/or the middle layer.

2. The micro-LED device of claim 1, wherein the supporting substrate includes an expandable film drawn out in an in-plane direction.

3. The micro-LED device of claim 1 or 2, wherein in each of the plurality of light-emitting device units, the device isolation region of the frontplane includes an insulator covering a side surface of the plurality of micro-LEDs, the insulator having at least one through hole for the metal plug.

4. The micro-LED device of claim 1, wherein
in each of the plurality of light-emitting device units, the frontplane has a flat surface, and
the flat surface is in contact with the middle layer.

5. The micro-LED device of claim 1, wherein
in each of the plurality of light-emitting device units, the middle layer includes an interlayer insulating layer having a flat surface, and
the interlayer insulating layer has a plurality of contact holes for coupling the plurality of first contact electrodes and the at least one second contact electrode with the electric circuit.

6. The micro-LED device of claim 1, wherein each of the plurality of light-emitting device units includes a plurality of micro-LEDs, each of the plurality of light-emitting device units having an electrically-conductive layer which electrically couples the second semiconductor layers of the micro-LEDs.

7. A method for producing a micro-LED device, comprising:
providing a multilayer stack which includes
a frontplane supported by a crystal growth substrate, the frontplane including a plurality of micro-LEDs, each of which includes a first semiconductor layer of a first conductivity type and a second semiconductor layer of a second conductivity type, and a device isolation region located between the plurality of micro-LEDs, the device isolation region including at least one metal plug electrically coupled with the second semiconductor layer, and
a middle layer supported by the frontplane, the middle layer including a plurality of first contact electrodes respectively electrically coupled with the first semiconductor layer of the plurality of micro-LEDs and at least one second contact electrode coupled with the metal plug;
forming a backplane on the multilayer stack, the backplane including an electric circuit electrically coupled with the plurality of micro-LEDs via the plurality of first contact electrodes and the at least one second contact electrode, the electric circuit including a plurality of thin film transistors;
dividing the multilayer stack and the backplane into a plurality of light-emitting device units;
covering the backplane with an expandable film and securing the multilayer stack and the backplane to the expandable film;
a delamination step which includes delaminating the multilayer stack, the backplane and the expandable film from the crystal growth substrate; and
expanding the expandable film, thereby enlarging a gap between the plurality of light-emitting device units,
wherein forming the backplane includes
depositing a semiconductor layer on the multilayer stack, and
patterning the semiconductor layer deposited on the multilayer stack.

8. The method of claim 7, wherein the expandable film is used as at least part of a flexible substrate supporting the plurality of light-emitting device units secured to the expandable film.

9. The method of claim 7, comprising transferring onto a supporting substrate the plurality of light-emitting device units secured to the expandable film.

10. The method of claim 7, wherein dividing the multilayer stack and the backplane into the plurality of light-emitting device units includes forming a cut groove from the backplane side so as to reach the crystal growth substrate.

11. The method of claim 7, wherein dividing the multilayer stack and the backplane into the plurality of light-emitting device units includes
securing the crystal growth substrate to a dicing tape, and
forming a cut groove from the backplane side so as to reach a middle section or a lower surface of the crystal growth substrate.

12. The method of claim 7, wherein dividing the multilayer stack and the backplane into the plurality of light-emitting device units includes forming a cut groove from the backplane side so as not to reach the crystal growth substrate.

13. The method of claim 12, wherein dividing the multilayer stack and the backplane into the plurality of light-emitting device units includes, after the delamination step, performing a breaking step which includes splitting the multilayer stack at the cut groove.

14. The method of claim 7, wherein the delamination step includes irradiating an interface between the crystal growth substrate and the frontplane with light transmitted through the crystal growth substrate.

15. A method for producing a micro-LED device, comprising:
providing a multilayer stack which includes
a frontplane supported by a crystal growth substrate, the frontplane including a plurality of micro-LEDs, each of which includes a first semiconductor layer of a first conductivity type and a second semiconductor layer of a second conductivity type, and a device isolation region located between the plurality of micro-LEDs, the device isolation region including at least one metal plug electrically coupled with the second semiconductor layer, and
a middle layer supported by the frontplane, the middle layer including a plurality of first contact electrodes respectively electrically coupled with the first semiconductor layer of the plurality of micro-LEDs and at least one second contact electrode coupled with the metal plug;
forming a backplane on the multilayer stack, the backplane including an electric circuit electrically coupled with the plurality of micro-LEDs via the plurality of first contact electrodes and the at least one second contact electrode, the electric circuit including a plurality of thin film transistors;
covering the backplane with an expandable film and securing the multilayer stack and the backplane to the expandable film;
a delamination step which includes delaminating the multilayer stack, the backplane and the expandable film from the crystal growth substrate;
performing dicing on the device isolation region, thereby dividing the multilayer stack and the backplane into a plurality of light-emitting device units each supported by the expandable film, and
expanding the expandable film, thereby enlarging a gap between the plurality of light-emitting device units,
wherein forming the backplane includes
depositing a semiconductor layer on the multilayer stack, and
patterning the semiconductor layer deposited on the multilayer stack.

16. The method of claim 15, wherein the expandable film is used as at least part of a flexible substrate supporting the plurality of light-emitting device units secured to the expandable film.

17. The method of claim 15, comprising transferring onto a supporting substrate the plurality of light-emitting device units secured to the expandable film.

18. The method of claim 15, wherein dividing the multilayer stack and the backplane into the plurality of light-emitting device units includes forming a cut groove in the multilayer stack and the backplane so as not to reach the expandable film.

19. The method of claim 18, wherein dividing the multilayer stack and the backplane into the plurality of light-emitting device units includes, after the dicing, performing a breaking step which includes splitting the multilayer stack at the cut groove.

20. The method of claim 15, wherein the delamination step includes irradiating an interface between the crystal growth substrate and the frontplane with light transmitted through the crystal growth substrate.
